(19) United States
(12) Patent Application Publication
(10) Pub. No.: US 2025/0089408 A1
(43) Pub. Date: Mar. 13, 2025

(54) DISPLAY DEVICE AND METHOD FOR FABRICATING THE SAME

(71) Applicant: Samsung Display Co., LTD., Yongin-si (KR)

(72) Inventors: Jung An LEE, Yongin-si (KR); Gwang Geun LEE, Yongin-si (KR); Ki Seong SEO, Yongin-si (KR); Ki Chang EOM, Yongin-si (KR); Yu Jin LEE, Yongin-si (KR)

(21) Appl. No.: 18/819,927

(22) Filed: Aug. 29, 2024

(30) Foreign Application Priority Data
Sep. 8, 2023 (KR) 10-2023-0119553

(51) Int. Cl. H01L 33/50; H01L 25/075; H01L 33/00; H01L 33/60; H01L 33/62

(52) U.S. Cl. CPC H10H 20/8512; H01L 25/0753; H10H 20/01; H10H 20/8515; H10H 20/856; H10H 20/857; H10H 20/0361; H10H 20/0363; H10H 20/0364; H10H 20/882

(57) ABSTRACT

The present disclosure may provide a display device and a method for manufacturing the same. According to one or more embodiments, a display device includes a pixel electrode above a substrate, a light-emitting element above the pixel electrode, and including a first semiconductor layer, an active layer, a second semiconductor layer, and a third semiconductor layer in sequence, the third semiconductor layer defining a recess exposing a portion of the second semiconductor layer, a via layer above the substrate, and surrounding at least a portion of the light-emitting element, and a common electrode above the light-emitting element and the via layer, and directly contacting the second semiconductor layer through the recess.

### CROSS-REFERENCE TO RELATED APPLICATION

The present application claims priority to, and the benefit of, Korean Patent Application No. 10-2023-0119553, filed on Sep. 8, 2023, in the Korean Intellectual Property Office, the entire disclosure of which is incorporated herein by reference.

### BACKGROUND

### 1. Field

The present disclosure relates to a display device, and to a method of manufacturing the same.

### 2. Description of the Related Art

Display devices are becoming increasingly important with the development of multimedia. In response to this, various types of display devices, such as organic light-emitting displays (OLED) and liquid crystal displays (LCD), are being used.

A device for displaying an image of a display device includes a display panel, such as an organic light-emitting display panel or a liquid crystal display panel. Among them, the light-emitting display panel may include a light-emitting element. For example, light-emitting diodes (LED) include organic light-emitting diodes (OLED) that utilize organic materials as light-emitting materials, inorganic light-emitting diodes that utilize inorganic materials as light-emitting materials, and/or the like.

### SUMMARY

Aspects of embodiments of the present disclosure provide a display device, and a method of manufacturing the same, which reduce the contact resistance of the common electrode.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments, a display device includes a pixel electrode above a substrate, a light-emitting element above the pixel electrode, and including a first semiconductor layer, an active layer, a second semiconductor layer, and a third semiconductor layer in sequence, the third semiconductor layer defining a recess exposing a portion of the second semiconductor layer, a via layer above the substrate, and surrounding at least a portion of the light-emitting element, and a common electrode above the light-emitting element and the via layer, and directly contacting the second semiconductor layer through the recess.

The display device may further include a partition wall unit above the common electrode, and defining a light-emitting area, and a wavelength conversion layer in a space formed by the partition wall unit, and filling the recess.

The wavelength conversion layer may include a wavelength conversion pattern including a base resin and wavelength conversion particles, or includes a light transmission pattern including a base resin and a scatterer.

The wavelength conversion layer may further include a scattering layer including the base resin and the scatterer below the wavelength conversion pattern.

A width of the recess may be between about 40% and about 90% of a width of the light-emitting element.

The display device may further include an element-insulating layer surrounding the light-emitting element in plan view, and a connection electrode between the first semiconductor layer and the pixel electrode.

The display device may further include a capping layer above and covering the common electrode.

A height of the via layer may be lower than a height of the light-emitting element.

The partition wall unit may include a first partition wall having an inverted taper shape with a width narrowing in a downward direction, and a first reflective layer surrounding the first partition wall in plan view.

The partition wall unit may include a second partition wall above the first partition wall and having an inverted taper shape with a width narrowing in the downward direction, and a second reflective layer surrounding the second partition wall in plan view.

The display device may further include an organic pattern layer between the connection electrode and the pixel electrode, and a sub-connection electrode extending along a side surface of the connection electrode to a side surface of the pixel electrode, and electrically connecting the connection electrode and the pixel electrode.

The pixel electrode may protrude outwardly further than a side of the organic pattern layer.

The partition wall unit may include a first partition wall having an inverted taper shape with a width narrowing in a downward direction, and a first reflective layer surrounding the first partition wall in plan view.

The partition wall unit may include a second partition wall above the first partition wall and having an inverted taper shape with a width narrowing in the downward direction, and a second reflective layer surrounding the second partition wall in plan view.

The display device may further include an overcoat layer and a color filter layer sequentially above the wavelength conversion layer and the partition wall unit.

According to one or more embodiments, a method of manufacturing display device includes bonding a light-emitting element, which includes a first semiconductor layer, an active layer, a second semiconductor layer, and a third semiconductor layer, to a pixel electrode above a substrate, forming a via layer having a height that is lower than a height of the light-emitting element above the substrate, forming a photoresist pattern surrounding the light-emitting element in plan view above the via layer, forming a recess in the third semiconductor layer to expose a portion of the second semiconductor layer by etching using the photoresist pattern as a mask, and forming a common electrode covering the via layer and the light-emitting element, and directly contacting the second semiconductor layer through the recess.

The method may further include forming a partition wall unit defining a light-emitting area above the common electrode, forming a reflective layer surrounding the partition wall unit in plan view, and forming a wavelength conversion layer in a space formed by the partition wall unit.

The method may further include forming a scattering layer including a base resin and a scatterer in the light-emitting area above the common electrode.

The light-emitting element may further include a connection electrode below the first semiconductor layer, wherein the bonding the light-emitting element to the pixel electrode includes melt bonding using the connection electrode above the pixel electrode.

The light-emitting element may further include a connection electrode below the first semiconductor layer, and wherein bonding the light-emitting element to the pixel electrode includes forming an organic pattern layer between the pixel electrode and the connection electrode, and forming a sub-connection electrode contacting the pixel electrode and the connection electrode.

According to a display device according to embodiments, the second semiconductor layer and the common electrode may be in direct contact to reduce the contact resistance of the common electrode. Thereby, power consumption may be improved.

However, the aspects of the present disclosure are not limited to the aforementioned aspects, and various other aspects are included in the present specification.

### BRIEF DESCRIPTION OF THE DRAWINGS

FIG. 1 is a perspective view illustrating a display device according to one or more embodiments.

FIGS. 2 and 3 are plan views illustrating a display device according to one or more embodiments.

FIG. 4 is a circuit diagram illustrating a first sub-pixel of a display panel according to one or more embodiments.

FIG. 5 is a circuit diagram illustrating a first sub-pixel of a display panel according to one or more other embodiments.

FIG. 6 is a cross-sectional view schematically illustrating a display device according to one or more embodiments.

FIG. 7 is an enlarged view schematically illustrating the first light-emitting area described with reference to FIG. 6.

FIG. 8 is an enlarged view of a light-emitting element according to one or more embodiments described with reference to FIG. 7.

FIG. 9 is a plan view of a pixel electrode and a light-emitting element according to the one or more embodiments described with reference to FIG. 7.

FIGS. 10 and 11 are plan views of a pixel electrode and a light-emitting element according to one or more embodiments modified from the one or more embodiments corresponding to FIG. 9.

FIG. 12 is a cross-sectional view schematically illustrating a display device according to one or more other embodiments.

FIG. 13 is an enlarged view schematically illustrating the first light-emitting area described with reference to FIG. 12.

FIG. 14 is a cross-sectional view schematically illustrating a display device according to one or more other embodiments.

FIG. 15 is an enlarged view schematically illustrating the first light-emitting area described with reference to FIG. 14.

FIG. 16 is a cross-sectional view schematically illustrating a display device according to one or more other embodiments.

FIG. 17 is an enlarged view schematically illustrating the first light-emitting area described with reference to FIG. 16.

FIG. 18 is a cross-sectional view schematically illustrating a display device according to one or more other embodiments.

FIG. 19 is an enlarged view schematically illustrating the first light-emitting area described with reference to FIG. 18.

FIG. 20 is a cross-sectional view schematically illustrating a display device according to one or more other embodiments.

FIG. 21 is an enlarged view schematically illustrating the first light-emitting area described with reference to FIG. 20.

FIGS. 22 to 38 are drawings to illustrate a method of manufacturing a display device according to one or more embodiments.

FIG. 39 is a diagram schematically showing a virtual reality device including a display device according to one or more embodiments.

FIG. 40 is a diagram schematically showing a smart device including a display device according to one or more embodiments.

FIG. 41 is a diagram schematically showing a vehicle including a display device according to one or more embodiments.

FIG. 42 is a diagram schematically showing a transparent display device including a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” and “at least one selected from the group consisting of X, Y, and Z,” may be construed as X only, Y only, Z only, any combination of two or more of X, Y, and Z, such as, for instance, XYZ, XYY, YZ, and ZZ, or any variation thereof. Similarly, the expressions “at least one of A and B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, directions DR1, DR2 and/or DR3 are not limited to directions corresponding to three axes of a rectangular coordinate system, and may be interpreted in a broader sense. For example, directions DR1, DR2 and the DR3 may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, applicant reserves the right to amend this specification, including the claims, to expressly recite any sub-range subsumed within the ranges expressly recited herein. All such ranges are intended to be inherently described in this specification such that amending to expressly recite any such subranges would comply with the requirements.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

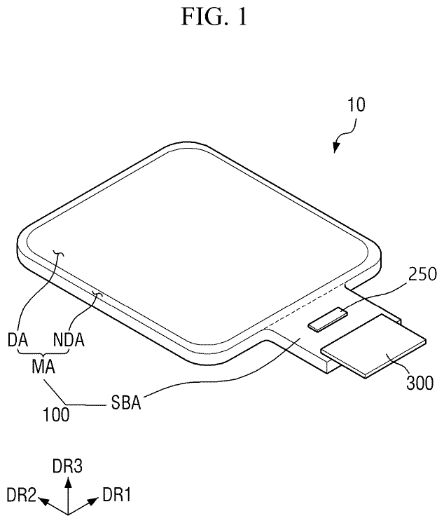

FIG. 1 is a perspective view illustrating a display device according to one or more embodiments.

Referring to FIG. 1, a display device 10 is a device for displaying video or still images, such as mobile phones, smart phones, tablet personal computers, and portable electronic devices, such as smart watches, watch phones, mobile communication terminals, electronic notebooks, e-books, portable electronic devices, such as portable multimedia players (PMP), navigation, and ultra mobile PCs (UMPC), as well as display screens for a variety of products, such as televisions, laptops, monitors, billboards, and the internet of things (IOT) device.

The display device 10 may be a light-emitting display device, such as an organic light-emitting display device utilizing an organic light-emitting diode, a quantum dot light-emitting display device including a quantum dot light-emitting layer, an inorganic light-emitting display device including an inorganic semiconductor, and a miniaturized light-emitting display device utilizing a micro or nano light-emitting diode (micro LED or nano LED). Hereinafter, the description focuses on the fact that the display device 10 is a micro-light-emitting display device, but the present disclosure is not limited thereto. On the other hand, the subminiature light-emitting diode is described herein as a micro light-emitting diode for convenience of explanation.

The display device 10 includes a display panel 100, a display-driving circuit 250, and a circuit board 300.

The display panel 100 may be formed as a rectangular-shaped plane having a short side in the first direction DR1, and a long side in the second direction DR2 that intersects the first direction DR1. A corner where the short side in the first direction DR1 and the long side in the second direction DR2 meet may be rounded to have a curvature (e.g., predetermined curvature) or may be formed at a right angle. The planar shape of the display panel 100 is not limited to a rectangle, and may be formed in other polygonal, circular, or oval shapes. The display panel 100 may be formed to be flat, but is not limited thereto. For example, the display panel 100 is formed at left and right ends and may include curved portions with a constant curvature or a changing curvature. Additionally, the display panel 100 may be formed to be flexible, such as to be able to be bent, curved, folded, or rolled.

The display panel 100 may include a main area MA and a sub-area SBA.

The main area MA may include a display area DA that displays an image, and a non-display area NDA that is a peripheral area of the display area DA. The display area DA may include a plurality of pixels that display an image. For example, the pixel may include a first sub-pixel that emits first light, a second sub-pixel that emits second light, and a third sub-pixel that emits third light.

The sub-area SBA may protrude from one side of the main area MA in the second direction DR2. Although FIG. 1 illustrates the sub-area SBA being unfolded, the sub-area SBA may be bent, and in this case, may be located on the bottom surface of the display panel 100. When the sub-area SBA is bent, it may overlap the main area MA in the third direction DR3, which is the thickness direction of the display panel 100. The display-driving circuit 250 may be located in the sub-area SBA.

The display-driving circuit 250 may generate signals and voltages for driving the display panel 100. The display-driving circuit 250 may be formed as an integrated circuit (IC), and may be attached to the display panel 100 using a chip-on-glass (COG) method, a chip-on-plastic (COP) method, or an ultrasonic bonding method but is not limited thereto. For example, the display-driving circuit 250 may be attached to the circuit board 300 using a chip-on-film (COF) method.

The circuit board 300 may be attached to one end of the sub-area SBA of the display panel 100. As such, the circuit board 300 may be electrically connected to the display panel 100 and the display-driving circuit 250. The display panel 100 and the display-driving circuit 250 may receive digital video data, timing signals, and driving voltages through the circuit board 300. The circuit board 300 may be a flexible printed circuit board, a regid printed circuit board, or a flexible film, such as a chip on film.

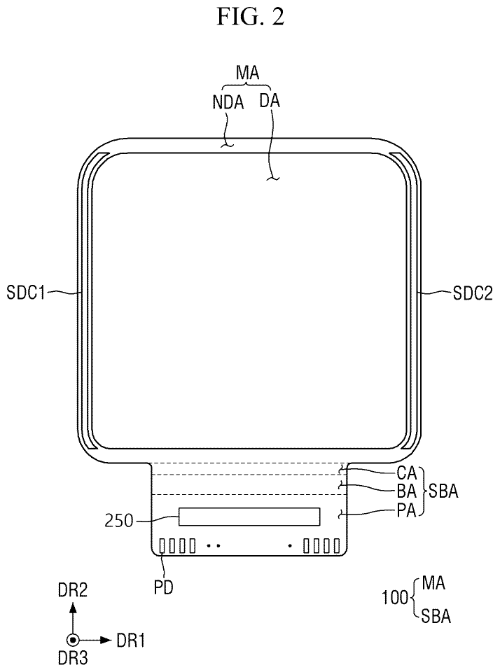

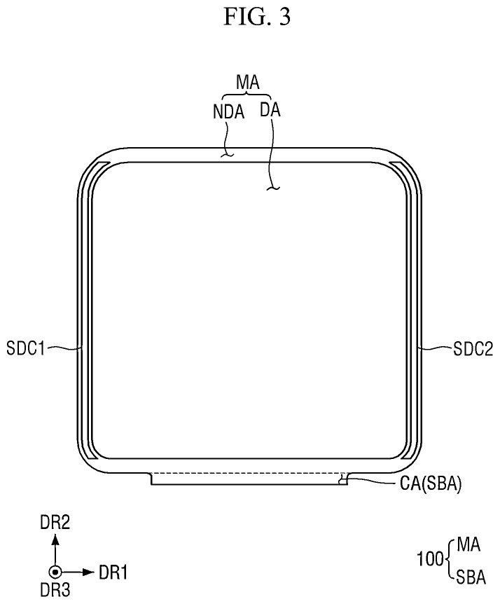

FIGS. 2 and 3 are plan views illustrating a display device according to one or more embodiments. FIG. 2 illustrates that the sub-area SBA is unfolded without being bent. FIG. 3 illustrates that the sub-area SBA is bent.

Referring to FIGS. 2 and 3, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed at the center of the main area MA.

The non-display area NDA may be placed adjacent to the display area DA. The non-display area NDA may be an area outside the display area DA. The non-display area NDA may be arranged to surround the display area DA. The non-display area NDA may be an edge area of the display panel 100.

A first scan driver SDC1 and a second scan driver SDC2 may be located in the non-display area NDA. The first scan driver SDC1 is located on one side (for example, the left side) of the display panel 100, and the second scan driver SDC2 is located on the other side (for example, the right side) of the display panel 100. However, it is not limited to. Each of the first scan driver SDC1 and the second scan driver SDC2 may be electrically connected to the display-driving circuit 250 through scan fan-out lines. Each of the first scan driver SDC1 and the second scan driver SDC2 may receive a scan control signal from the display-driving circuit 250, may generate scan signals according to the scan control signal, and may output the scan signals to the scan lines.

The sub-area SBA may protrude from one side of the main area MA in the second direction DR2. The length of the sub-area SBA in the second direction DR2 may be less than the length of the main area MA in the second direction DR2. The length of the sub-area SBA in the first direction DR1 is less than the length of the main area MA in the first direction DR1, or may be substantially equal to the length of the main area MA in the first direction DR1. The sub-area SBA may be curved, and may be located at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display-driving circuit 250 are located. The display-driving circuit 250 may be attached to the driving pads of the pad area PA using a conductive adhesive member, such as an anisotropic conductive film. The circuit board 300 may be attached to the pads PD of the pad area PA using a conductive adhesive member, such as an anisotropic conductive film. One side of the pad area PA may be in contact with the bending area BA.

The bending area BA is a bent area. When the bending area BA is bent, the pad area PA may be located below the connection area CA and below the main area MA. The bending area BA may be located between the connection area CA and the pad area PA. One side of the bending area BA may be in contact with the connection area CA, and the other side of the bending area BA may be in contact with the pad area PA.

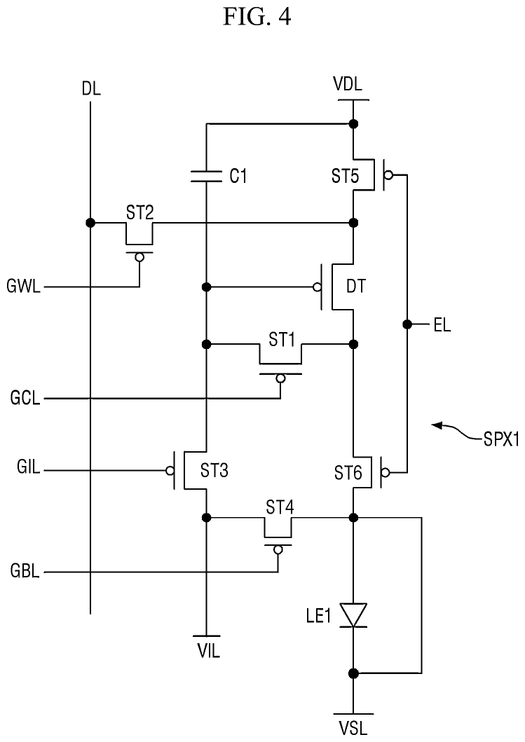

FIG. 4 is a circuit diagram illustrating a first sub-pixel of a display panel according to one or more embodiments.

Referring to FIG. 4, the first sub-pixel SPX1 according to one or more embodiments may be connected to scan lines GWL, GIL, GCL, and GBL, one or more light-emitting lines EL, and one or more data lines DL. For example, the first sub-pixel SPX1 may be connected to a write scan line GWL, an initialization scan line GIL, a control scan line GCL, a bias scan line GBL, a light-emitting line EL, and a data line DL.

The first sub-pixel SPX1 according to one or more embodiments includes a driving transistor DT, switch elements, a capacitor C1, and a first light-emitting element LE1. The switch elements include first to sixth transistors ST1, ST2, ST3, ST4, ST5, and ST6.

The driving transistor DT includes a gate electrode, a first electrode, and a second electrode. The driving transistor DT controls the drain-source current (hereinafter referred to as “driving current”) flowing between the first electrode and the second electrode according to the data voltage applied to the gate electrode.

The first light-emitting element LE1 may be a micro light-emitting diode. The first light-emitting element LE1 emits light according to the driving current. The amount of light emitted from the first light-emitting element LE1 may be proportional to the driving current. An anode electrode of the first light-emitting element LE1 may be connected to the first electrode of the fourth transistor ST4 and the second electrode of the sixth transistor ST6, a cathode electrode may be connected to the second power supply line VSL to which the second power supply voltage is applied.

The capacitor C1 is formed between the second electrode of the driving transistor DT and the first power supply line VDL to which the first power supply voltage is applied. The first power supply voltage may be at a higher level than the second power supply voltage. One electrode of the capacitor C1 may be connected to the second electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon or oxide semiconductor.

The gate electrode of the second transistor ST2 may be connected to the write scan line GWL. The gate electrode of the first transistor ST1 may be connected to the control scan line GCL. The gate electrode of the third transistor ST3 may be connected to the initialization scan line GIL. The gate electrode of the fourth transistor ST4 may be connected to the bias scan line GBL. Because the first to sixth transistors ST1, ST2, ST3, ST4, ST5, and ST6 are formed as p-type MOSFET, they may be turned on when a scan signal of the gate low voltage and an emission signal are applied to the control scan line GCL, the initialization scan line GIL, the write scan line GWL, the bias scan line GBL, and the light-emitting line EL, respectively. One electrode of the third transistor ST3 and one electrode of the fourth transistor ST4 may be connected to an initialization voltage line VIL.

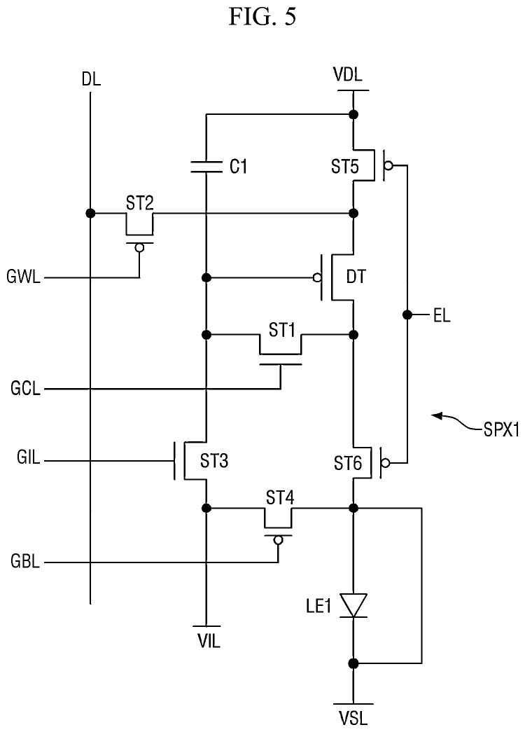

FIG. 5 is a circuit diagram illustrating a first sub-pixel of a display panel according to one or more other embodiments.

Referring to FIG. 5, the driving transistor DT, the second transistor ST2, the fourth transistor ST4, the fifth transistor ST5, and the sixth transistor ST6 are formed as p-type MOSFET, and the first transistor ST1 and the third transistor ST3 may be formed as n-type MOSFET. The active layer of each of the driving transistor DT, the second transistor ST2, the fourth transistor ST4, the fifth transistor ST5, and the sixth transistor ST6 formed as the p-type MOSFET may be formed of polysilicon, and the active layer of each of the first transistor ST1 and the third transistor ST3 formed as the n-type MOSFET may be formed of the oxide semiconductor. In this case, transistors formed of polysilicon and transistors formed of oxide semiconductors may be arranged in different layers.

Because the first transistor ST1 and the third transistor ST3 are formed as n-type MOSFET, the first transistor ST1 may be turned on when a control scan signal with a gate high voltage is applied to the control scan line GCL, and the third transistor ST3 may be turned on when an initialization scan signal is applied to the initialization scan line GIL. In comparison, the second transistor ST2, the fourth transistor ST4, the fifth transistor ST5, and the sixth transistor ST6 are formed as p-type MOSFET, so they may be turned on when a scan signal with a gate low voltage and an emission signal are applied to the write scan line GWL, the bias scan line GBL, and the light-emitting line EL, respectively.

Alternatively, the fourth transistor ST4 in FIG. 4 may be formed of the n-type MOSFET. In this case, the active layer of each fourth transistor ST4 may be formed of the oxide semiconductor. When the fourth transistor ST4 is formed of n-type MOSFET, it may be turned on when a bias scan signal of a gate high voltage is applied to the bias scan line GBL.

Alternatively, in one or more embodiments, the first to sixth transistors ST1, ST2, ST3, ST4, ST5, and ST6 and the driving transistor DT may all be formed as n-type MOSFET.

Meanwhile, the circuit diagram of the second sub-pixel and the third sub-pixel according to one or more embodiments are substantially the same as the circuit diagram of the first sub-pixel SPX1 described in conjunction with FIGS. 4 and 5, so a description thereof will be omitted.

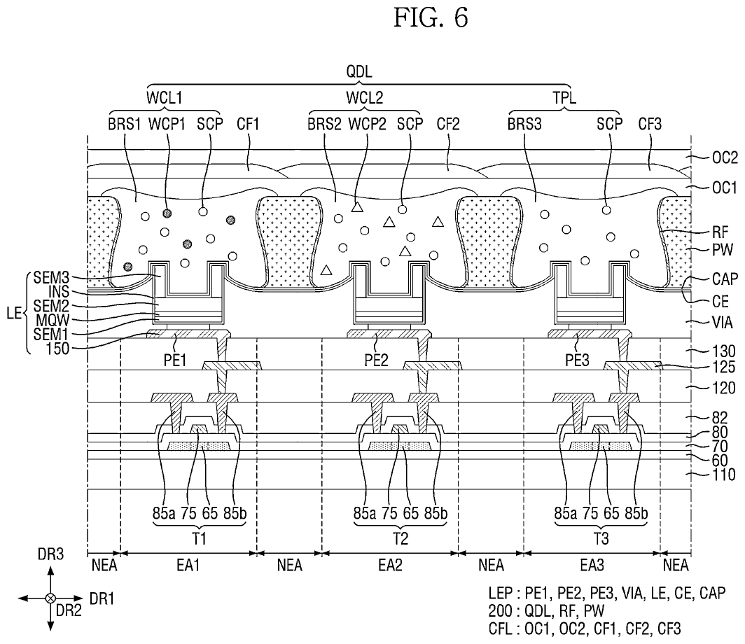

FIG. 6 is a cross-sectional view schematically illustrating a display device according to one or more embodiments.

Referring to FIG. 6, the display device 10 may include a substrate 110, a light-emitting element unit LEP, a wavelength control unit 200, and a color filter layer CFL.

The substrate 110 may be an insulating substrate. The substrate 110 may include a transparent material. For example, the substrate 110 may include a transparent insulating material, such as glass, quartz, etc. The substrate 110 may be a rigid substrate. However, the substrate 110 is not limited thereto and may include plastic, such as polyimide, and may have flexible characteristics that allow it to be curved, bent, folded, or rolled. A plurality of light-emitting areas EA1, EA2, and EA3 and a non-emitting area NEA may be defined in the substrate 110.

Switching elements T1, T2, and T3 may be located on the substrate 110. In one or more embodiments, the first switching element T1 may be located in the first light-emitting area EA1 of the substrate 110, the second switching element T2 may be located in the second light-emitting area EA2, and the third switching element T3 may be located in the third light-emitting area EA3. However, it is not limited thereto, and in one or more other embodiments, at least one of the first switching element T1, the second switching element T2, and the third switching element T3 may be located in the non-emitting area NEA.

In one or more embodiments, the first switching element T1, the second switching element T2, and the third switching element T3 may each be a thin film transistor including amorphous silicon, polysilicon, or an oxide semiconductor. In one or more embodiments, a plurality of signal lines (e.g., gate lines, data lines, power supply lines, etc.) that transmit signals to each switching element may be further positioned on the substrate 110.

Each switching element T1, T2, and T3 may include a semiconductor layer 65, a gate electrode 75, a source electrode 85a, and a drain electrode 85b.

For example, a buffer layer 60 may be located on the substrate 110 (“located on,” as used herein, may mean “above”). The buffer layer 60 may cover the entire surface of the substrate 110. The buffer layer 60 includes silicon nitride, silicon oxide, or silicon oxynitride, and may be made of a single layer or a double layer thereof.

The semiconductor layer 65 may be located on (e.g., above) the buffer layer 60. The semiconductor layer 65 may form a channel for each switching element T1, T2, and T3. The semiconductor layer 65 may include amorphous silicon, polycrystalline silicon, or an oxide semiconductor. For example, the oxide semiconductor may include a binary compound (ABₓ), a ternary compound (ABₓC_{y}), or a quaternary compound (ABₓC_{y}D_{z}) containing, for example, indium, zinc, gallium, tin, titanium, aluminum, hafnium (Hf), zirconium (Zr), magnesium (Mg), and/or the like. In one or more embodiments, the semiconductor layer 65 may include indium tin zinc oxide (IGZO).

The gate-insulating layer 70 may be located on the semiconductor layer 65. The gate-insulating layer 70 may include a silicon compound, metal oxide, or the like. For example, the gate-insulating layer 70 may include a silicon oxide, a silicon nitride, a silicon oxynitride, an aluminum oxide, a tantalum oxide, a hafnium oxide, a zirconium oxide, a titanium oxide, and/or the like. In one or more embodiments, the gate-insulating layer 70 may include silicon oxide.

The gate electrode 75 may be located on the gate-insulating layer 70. The gate electrode 75 may overlap the semiconductor layer 65. The gate electrode 75 may include a conductive material. The gate electrode 75 may include a metal oxide, such as ITO, IZO, ITZO, In₂O₃, or a metal, such as copper (Cu), titanium (Ti), aluminum (Al), molybdenum (Mo), tantalum (Ta), calcium (Ca), chromium (Cr), magnesium (Mg), or nickel (Ni). For example, the gate electrode 75 may be made of a Cu/Ti double layer in which an upper layer of copper is stacked on a lower layer of titanium, but is not limited thereto.

A first interlayer insulating layer 80 and a second interlayer insulating layer 82 may be located on the gate electrode 75. The first interlayer insulating layer 80 may be directly located on the gate electrode 75, and the second interlayer insulating layer 82 may be directly located on the first interlayer insulating layer 80. The first interlayer insulating layer 80 and the second interlayer insulating layer 82 may each include an inorganic insulating material, such as silicon oxide, silicon nitride, silicon oxynitride, hafnium oxide, aluminum oxide, titanium oxide, tantalum oxide, zinc oxide, and/or the like. However, the present disclosure is not limited thereto, and the second interlayer insulating layer 82 may include an organic insulating material capable of flattening the lower-level difference. In one or more embodiments, two interlayer insulating layers, the first interlayer insulating layer 80 and the second interlayer insulating layer 82, are illustrated and described, but the present disclosure is not limited thereto, and only one interlayer insulating layer may be located.

The source electrode 85a and the drain electrode 85b may be located on the second interlayer insulating layer 82. The source electrode 85a and the drain electrode 85b may contact the semiconductor layer 65 through contact holes through the first interlayer insulation layer 80, the second interlayer insulation layer 82, and the gate-insulating layer 70, respectively. The source electrode 85a and the drain electrode 85b may include metal oxides, such as ITO, IZO, ITZO, In₂O₃, or metals, such as copper (Cu), titanium (Ti), aluminum (Al), molybdenum (Mo), tantalum (Ta), calcium (Ca), chromium (Cr), magnesium (Mg), and/or nickel (Ni). For example, the source electrode 85a and the drain electrode 85b may be made of a Cu/Ti double layer in which an upper layer of copper is stacked on a lower layer of titanium, but is not limited thereto.

A first planarization layer 120 may be located on the first switching element T1, the second switching element T2, and the third switching element T3. The first planarization layer 120 may include an organic material. For example, the first planarization layer 120 may include acrylic resin, epoxy resin, imide resin, ester resin, etc. In one or more embodiments, the first planarization layer 120 may include a positive photosensitive material or a negative photosensitive material.

A pixel connection electrode 125 may be located on the first planarization layer 120. The pixel connection electrode 125 may correspond to, and may be electrically connected to, each of the first switching element T1, the second switching element T2, and the third switching element T3. The pixel connection electrode 125 may connect the pixel electrodes PE1, PE2, and PE3 described later to the switching elements T1, T2, and T3 described above. The pixel connection electrode 125 may contact the switching elements T1, T2, and T3 through a contact hole penetrating the first planarization layer 120.

A second planarization layer 130 may be located on the first planarization layer 120 and the pixel connection electrode 125. The second planarization layer 130 may flatten the lower-level difference, and may include the same material as the first planarization layer 120 described above.

The light-emitting element unit LEP may be located on the second planarization layer 130. The light-emitting element unit LEP may include a plurality of pixel electrodes PE1, PE2, and PE3, a plurality of light-emitting elements LE, a via layer VIA, and a common electrode CE. Additionally, the light-emitting element unit LEP may further include a capping layer CAP covering the common electrode CE.

The plurality of pixel electrodes PE1, PE2, and PE3 may include a first pixel electrode PE1, a second pixel electrode PE2, and a third pixel electrode PE3. The first pixel electrode PE1, the second pixel electrode PE2, and the third pixel electrode PE3 may serve as the first electrode of the light-emitting element LE, and may be an anode electrode or a cathode electrode. The first pixel electrode PE1 may be located in the first light-emitting area EA1, the second pixel electrode PE2 may be located in the second light-emitting area EA2, and the third pixel electrode PE3 may be located in the third light-emitting area EA3. The light-emitting elements LE may be arranged regularly with certain rules. For example, the light-emitting elements LE may be arranged to be spaced apart from each other at regular intervals.

In one or more embodiments, the first pixel electrode PE1 may overlap with the first light-emitting area EA1, the second pixel electrode PE2 may overlap with the second light-emitting area EA2, and the third pixel electrode PE3 may overlap with the third light-emitting area EA3.

Each pixel electrode PE1, PE2, and PE3 may be directly connected to the respective pixel connection electrode 125 through a contact hole penetrating the second planarization layer 130, and may be electrically connected to the respective switching elements T1, T2, and T3 through the pixel connection electrode 125. The first pixel electrode PE1, the second pixel electrode PE2, and the third pixel electrode PE3 may include metal. The metal may include, for example, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. Additionally, the first pixel electrode PE1, the second pixel electrode PE2, and the third pixel electrode PE3 may have a multi-layer structure in which two or more metal layers are stacked. For example, the first pixel electrode PE1, the second pixel electrode PE2, and the third pixel electrode PE3 may have a two-layer structure in which a copper layer is stacked on a titanium layer, but the structure is not limited thereto.

The plurality of light-emitting elements LE may be located on the first pixel electrode PE1, the second pixel electrode PE2, and the third pixel electrode PE3. The light-emitting elements LE may be inorganic light-emitting elements made of an inorganic material, such as GaN.

The light-emitting elements LE may be located in each of the first light-emitting area EA1, the second light-emitting area EA2, and the third light-emitting area EA3. The light-emitting element LE may be a vertical light-emitting diode element extending lengthwise in the third direction DR3. That is, the length of the light-emitting element LE in the third direction DR3 may be longer than the length/width in the horizontal direction. The length/width in the horizontal direction indicates the length/width in the first direction DR1 or the length/width in the second direction DR2. For example, the length/width of the light-emitting element LE in the first direction DR1 or the length/width in the second direction DR2 may be about 7 μm to about 10 μm, but is not limited thereto. Also, the length of the light-emitting element LE in the third direction DR3 may be about 1 μm to about 5 μm. However, the present disclosure is not limited to this, and the length of the light-emitting element LE in the third direction DR3 may be equal to or less than the length in the horizontal direction.

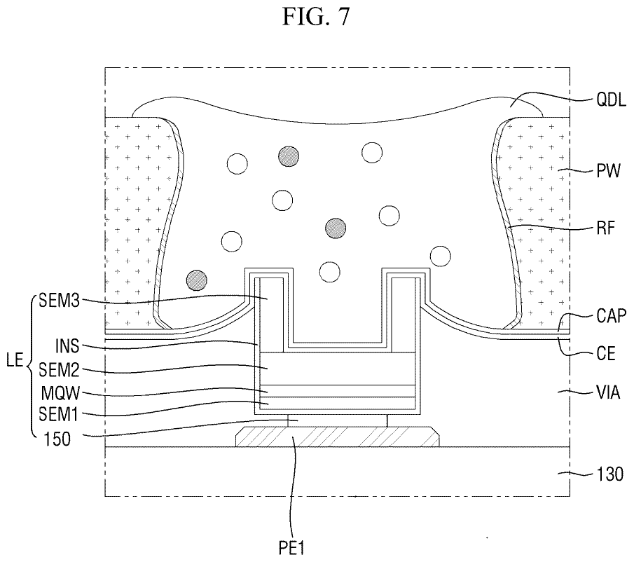

The light-emitting element LE may be a micro light-emitting diode element. The light-emitting element LE includes a recess that is convex from top to bottom. The structure of the light-emitting element LE will be described with reference to FIGS. 7 to 10.

The via layer VIA may be located on the second planarization layer 130 and the pixel electrodes PE1, PE2, and PE3. The via layer VIA covers the pixel electrodes PE1, PE2, and PE3, and may flatten the lower step so that the common electrode CE, which will be described later, may be formed. The height of the via layer VIA may be less than the height of the light-emitting element LE.

The via layer VIA may include, for example, acrylic resin, epoxy resin, phenolic resin, polyamides resin, polyimides rein, unsaturated polyesters resin, poly phenylenethers resin, polyphenylenesulfides resin, or benzocyclobutene (BCB).

The common electrode CE may be located on the via layer VIA and the plurality of light-emitting elements LE. For example, the common electrode CE is located on one surface of the substrate 110 on which the light-emitting element LE is formed, and may be located entirely in the display area DA of the substrate 110. The common electrode CE is overlapping each of the light-emitting areas EA1, EA2, and EA3 and the non-emitting area NEA, and may be thin enough to allow light to be emitted.

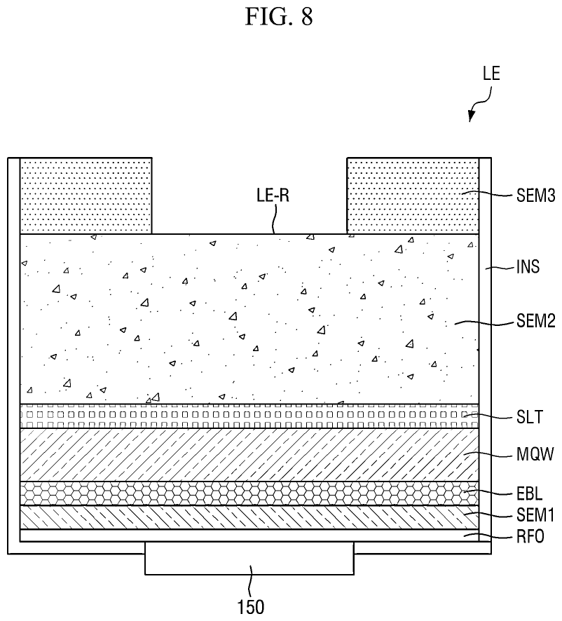

The common electrode CE may be directly located on the top surface of the plurality of light-emitting elements LE. The common electrode CE may directly contact the second semiconductor layer (SEM2 in FIG. 8) exposed through an opening formed on the top surface of the light-emitting element LE. As shown in FIG. 6, the common electrode CE covers the via layer VIA and the plurality of light-emitting devices LE, and may be a common layer located in common connection with the plurality of light-emitting elements LE.

Because the common electrode CE is located entirely on the substrate 110, and may apply a common voltage, the common electrode CE may include a material with low resistance. Additionally, the common electrode CE may be formed to be thin to facilitate light transmission. For example, the common electrode CE may include a metal material with low resistance, such as aluminum (Al), silver (Ag), copper (Cu), or the like, or a metal oxide, such as ITO, IZO, ITZO, or the like. The thickness of the common electrode CE may be about 10 Å to about 200 Å, but is not limited thereto.

The above-described light-emitting elements LE may receive a pixel voltage or anode voltage from each pixel electrode PE1, PE2, and PE3, and may receive a common voltage through the common electrode CE. The light-emitting elements LE may emit light with a luminance (e.g., predetermined luminance) depending on a voltage difference between the pixel voltage and the common voltage. In one or more embodiments, by arranging a plurality of light-emitting elements LE, that is, inorganic light-emitting diodes, on the pixel electrodes PE1, PE2, and PE3, the disadvantages of organic light-emitting diodes being vulnerable to external moisture or oxygen may be reduced or eliminated, and the lifespan and reliability may be improved.

The capping layer CAP may be further located on the common electrode CE. The capping layer CAP may cover the light-emitting element unit LEP located therebelow, and may protect the light-emitting element unit LEP from moisture or debris. The capping layer CAP may include an inorganic material. For example, the capping layer CAP may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxide. Meanwhile, the drawing shows that the capping layer CAP is formed as one layer, but the present disclosure is not limited thereto. For example, the capping layer CAP may be formed of multiple layers in which inorganic layers containing at least one of the materials that the capping layer CAP may include are alternately stacked. The thickness of the capping layer CAP may range from about 0.05 μm to about 2 μm, but is not limited thereto. The capping layer CAP may be omitted.

The wavelength control unit 200 may be located on the light-emitting element unit LEP. The wavelength control unit 200 may include a partition wall unit PW, a wavelength conversion layer QDL, and a reflective layer RF.

The partition wall unit PW is located on a capping layer CPA, and may compartmentalize a plurality of light-emitting areas EA1, EA2, and EA3. The partition wall unit PW may extend in the first direction DR1 and the second direction DR2, and may be formed in a grid-like pattern throughout the display area DA. Further, the partition wall unit PW may not overlap with the plurality of light-emitting areas EA1, EA2, and EA3, and may overlap with the non-emitting area NEA.

The partition wall unit PW may include a negative photosensitive material, and may have an inverted tapered shape. The partition wall unit PW may serve to provide a space for the wavelength conversion layer QDL to be formed. The partition wall unit PW may have a relatively large thickness to provide a space in which the wavelength conversion layer QDL is formed. For example, the height of the partition wall unit PW may range from about 8 μm to about 12 μm. The partition wall unit PW may include an organic insulating material. The organic insulating material may include, for example, epoxy resin, acrylic resin, cardo resin, or imide resin.

In one or more embodiments, the partition wall unit PW may block the transmission of light in the non-emitting area NEA. The partition wall unit PW may further include a light-blocking material, and may include a dye or pigment having light-blocking properties. For example, the partition wall unit PW may be a black matrix. External light incident from the outside of the display device 10 may cause a problem that distorts the color gamut of the wavelength control unit 200. According to one or more embodiments, the partition wall unit PW including the light-blocking material is located in the wavelength control unit 200 so that at least a portion of external light is absorbed by the light-blocking member. Therefore, color distortion caused by external light reflection may be reduced. Furthermore, the partition wall unit PW including a light-blocking material may reduce or prevent color mixing from occurring due to light intruding between adjacent light-emitting areas, thereby further improving the color reproduction rate.

The reflective layer RF may be located on the inner surface of the space formed by the partition wall unit PW. The reflective layer RF may not overlap the light-emitting areas EA1, EA2, and EA3, and may overlap the non-emitting area NEA.

The reflective layer RF may reflect light emitted from the light-emitting elements LE and traveling laterally upward (e.g., in the third direction DR3). The reflective layer RF may include a metal material with high light reflectance. For example, the reflective layer RF may include aluminum or silver, or an alloy thereof.

The wavelength conversion layer QDL may be located in the space formed by the partition wall unit PW. The wavelength conversion layer QDL may convert or shift the peak wavelength of incident light into light of another corresponding peak wavelength, and may emit the light. The wavelength conversion layer QDL may convert the blue first light emitted from the light-emitting element LE into a red second light or into a green third light, or may transmit the blue first light as is.

The wavelength conversion layer QDL may be located in each light-emitting area EA1, EA2, and EA3 compartmentalized by the partition wall unit PW, and may be spaced apart from each other. That is, the wavelength conversion layer QDL may be formed in the island pattern spaced apart from each other. The wavelength conversion layer QDL may overlap the first light-emitting area EA1, the second light-emitting area EA2, and the third light-emitting area EA3, respectively. In one or more embodiments, each of the wavelength conversion layer QDL may completely overlap the first light-emitting area EA1, the second light-emitting area EA2, and the third light-emitting area EA3.

The wavelength conversion layer QDL includes a first wavelength conversion pattern WCL1 overlapping with the first light-emitting area EA1, a second wavelength conversion pattern WCL2 overlapping with the second light-emitting area EA2, and a light transmission pattern TPL overlapping the third light-emitting area EA3.

The first wavelength conversion pattern WCL1 may overlap the first light-emitting area EA1. The first wavelength conversion pattern WCL1 may convert or shift the peak wavelength of incident light into light of another corresponding peak wavelength, and may emit the light. In one or more embodiments, the first wavelength conversion pattern WCL1 may convert blue first light emitted from the light-emitting element LE of the first light-emitting area EA1 into second light, which is red light having a single peak wavelength in the range of about 610 nm to about 650 nm, and may emit the red light.

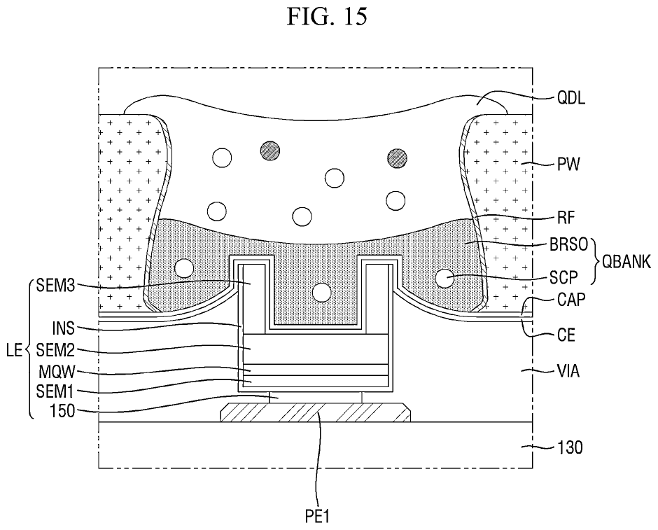

The first wavelength conversion pattern WCL1 may include a first base resin BRS1, a first wavelength conversion particle WCP1, and a scatterer SCP. The first base resin BRS1 may be the same material as the base resin BRS0 (for example, see FIG. 15) of a scattering layer QBANK (e.g., see FIG. 15), but is not limited thereto. The first base resin BRS1 may include a light-transmitting organic material. For example, the first base resin BRS1 may include epoxy resin, acrylic resin, cardo resin, or imide resin.

The first wavelength conversion particle WCP1 may convert the first light incident from the light-emitting element LE into the second light. For example, the first wavelength conversion particle WCP1 may convert light in the blue wavelength band into light in the red wavelength band. The first wavelength conversion particle WCP1 may be a quantum dot (QD), a quantum rod, a fluorescent material, or a phosphorescent material. For example, quantum dots may be particulate materials that emit a corresponding color as electrons transition from the conduction band to the valence band.

The quantum dots may be semiconductor nanocrystalline materials. Depending on its composition and size, the quantum dot may have a corresponding bandgap to absorb light and to emit light with a unique wavelength. Examples of the semiconductor nanocrystals of the quantum dots include IV Group nanocrystals, II-VI Group compound nanocrystals, III-V Group compound nanocrystals, IV-VI Group compound nanocrystals, or combinations thereof.

The Group II-VI compound may be a binary compound selected from the group including CdSe, CdTe, ZnS, ZnSe, ZnTe, ZnO, HgS, HgSe, HgTe, MgSe, MgS, and mixtures thereof; a ternary compound selected from the group including InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and/or a quaternary compound selected from the group including HgZnTeS, CdZnSeS, CdZnSeTe, CdZnSTe, CdHgSeS, CdHgSeTe, CdHgSTe, HgZnSeS, HgZnSeTe, and mixtures thereof.

The Group III-V compound may be a binary compound selected from the group including GaN, GaP, GaAs, GaSb, AlN, AlP, AlAs, AlSb, InN, InP, InAs, InSb, and mixtures thereof; a ternary compound selected from the group including GaNP, GaNAs, GaNSb, GaPAs, GaPSb, AlNP, AlNAs, AlNSb, AlPAS, AlPSb, InGaP, InNP, InAlP, InNAs, InNSb, InPAs, InPSb, and mixtures thereof; and/or a quaternary compound selected from the group including GaAlNAs, GaAlNSb, GaAlPAs, GaAlPSb, GaInNP, GaAlNP, GaInNAs, GaInNSb, GaInPAs, GaInPSb, InAlNP, InAlNAs, InAlNSb, InAlPAs, InAlPSb, and mixtures thereof.

The Group IV-VI compounds may be selected from the group including binary compounds selected from the group including SnS, SnSe, SnTe, PbS, PbSe, PbTe, and mixtures thereof; ternary compounds selected from the group including SnSeS, SnSeTe, SnSTe, PbSeS, PbSeTe, PbSTe, SnPbS, SnPbSe, SnPbTe, and mixtures thereof; and/or a quaternary compound selected from the group including SnPbSSe, SnPbSeTe, SnPbSTe, and/or mixtures thereof. The Group IV element may be selected from the group including Si, Ge, and mixtures thereof. The Group IV compound may be a binary compound selected from the group including SiC, SiGe, and mixtures thereof.

The binary, ternary, or quaternary compounds may be present in the particle at a uniform concentration or may be present in the same particle with a partially different concentration distribution. The quantum dot may also have a core-shell structure in which one quantum dot surrounds another. The interface of the core and shell may have a concentration gradient where the concentration of an element present in the shell decreases toward the center.

In one or more embodiments, the quantum dot may have a core-shell structure including a core including a nanocrystal as described above, and a shell surrounding the core. The shell of the quantum dot may act as a protective layer to reduce or prevent the likelihood of chemical denaturation of the core to maintain semiconductor properties, and/or may act as a charging layer to impart electrophoretic properties to the quantum dot. The shell may be monolayer or multilayer. Examples of shells for the quantum dots include oxides of metals or non-metals, semiconductor compounds, or combinations thereof.

For example, the oxides of said metals or non-metals may be binary compounds, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or ternary compounds, such as MgAl₂O₄, CoFe₂O₄, NiFe₂O₄, CoMn₂O₄, but the present disclosure is not limited thereto.

In addition, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but are not limited thereto.

The second wavelength conversion pattern WCL2 may overlap the second light-emitting area EA2. The second wavelength conversion pattern WCL2 may emit light by converting or shifting the peak wavelength of incident light into light of another corresponding peak wavelength. In one or more embodiments, the second wavelength conversion pattern WCL2 converts the blue first light emitted from the light-emitting element LE of the second light-emitting area EA2 into green third light having a peak wavelength in the range of about 510 nm to about 550 nm, and may emit the light.

The second wavelength conversion pattern WCL2 may include a second base resin BRS2, and a second wavelength conversion particle WCP2 and the scatterer SCP dispersed in the second base resin BRS2.

The second base resin BRS2 may be made of a material with high light transmittance, may be made of the same material as the first base resin BRS1, or may include at least one of the materials described above as their constituent materials.

The second wavelength conversion particle WCP2 may convert or shift the peak wavelength of incident light to another corresponding peak wavelength. In one or more embodiments, the second wavelength conversion particle WCP2 may convert the blue first light provided from the light-emitting element LE into green third light having a peak wavelength in the range of about 510 nm to about 550 nm, and may emit the light. Examples of the second wavelength conversion particle WCP2 include quantum dots, quantum rods, or phosphors. A more specific description of the second wavelength conversion particle WCP2 is substantially the same as or similar to that described above in the description of the first wavelength conversion particle WCP1 and will not be repeated.

The light transmission pattern TPL may be arranged to overlap the third light-emitting area EA3. The light transmission pattern TPL may transmit incident light. The light transmission pattern TPL may directly transmit the blue first light emitted from the light-emitting element LE located in the third light-emitting area EA3. The light transmission pattern TPL may include a third base resin BRS3, and the scatterer SCP dispersed in the third base resin BRS3. Because the third base resin BRS3 is substantially the same as or similar to the above-described first base resin BRS1, repeated description thereof will be omitted.

Meanwhile, the color filter layer CFL may be located on the wavelength control unit 200. The color filter layer CFL may include a first overcoat layer OC1, a first color filter CF1, a second color filter CF2, a third color filter CF3, and a second overcoat layer OC2.

The first overcoat layer OC1 may be located on the wavelength control unit 200. The first overcoat layer OC1 may be directly located on the wavelength control unit 200. The first overcoat layer OC1 may be located entirely over the display area DPA, and may have a flat surface. The first overcoat layer OC1 may flatten the step formed by the lower wavelength control unit 200 to facilitate the formation of the color filter layer CFL.

The first overcoat layer OC1 may include a light-transmitting organic material. For example, the first overcoat layer OC1 may include epoxy resin, acrylic resin, cardo resin, or imide resin.

The first color filter CF1, the second color filter CF2, and the third color filter CF3 may be located on the first overcoat layer OC1. The first color filter CF1 may be located in the first light-emitting area EA1, the second color filter CF2 may be located in the second light-emitting area EA2, and the third color filter CF3 may be located in the third light-emitting area EA3.

The first color filter CF1, the second color filter CF2, and the third color filter CF3 may include a colorant, such as the dye or pigment that absorbs wavelengths other than the corresponding color wavelength. The first color filter CF1 may selectively transmit the second light (e.g., red light), and may block or absorb the first light (e.g., blue light) and the third light (e.g., green light). The second color filter CF2 may selectively transmit the third light (e.g., green light), and may block or absorb the first light (e.g., blue light) and the second light (e.g., red light). The third color filter CF3 may selectively transmit the first light (e.g., blue light), and may block or absorb the second light (e.g., red light) and the third light (e.g., green light). For example, the first color filter CF1 may be a red color filter, the second color filter CF2 may be a green color filter, and the third color filter CF3 may be a blue color filter.

In one or more embodiments, the light incident on the first color filter CF1 may be light converted to second light in the first wavelength conversion pattern WCL1, the light incident on the second color filter CF2 may be light converted to third light in the second wavelength conversion pattern WCL2, and the light incident on the third color filter CF3 may be first light transmitted through the light transmission pattern TPL. As a result, the second light transmitted through the first color filter CF1, the third light transmitted through the second color filter CF2, and the first light transmitted through the third color filter CF3 may be emitted to achieve full color.

The first color filter CF1, the second color filter CF2, and the third color filter CF3 may absorb a portion of the light entering from the outside of the display device 10 to reduce the reflected light caused by external light. Accordingly, the first color filter CF1, the second color filter CF2, and the third color filter CF3 may reduce or prevent color distortion due to reflection of external light.

The plane area of each of the first color filter CF1, the second color filter CF2, and the third color filter CF3 may be larger than the planar area of each of the plurality of light-emitting areas EA1, EA2, and EA3. For example, the planar area of the first color filter CF1 may be larger than the planar area of the first light-emitting area EA1. The planar area of the second color filter CF2 may be larger than the planar area of the second light-emitting area EA2. The planar area of the third color filter CF3 may be larger than the planar area of the third light-emitting area EA3. However, it is not limited thereto, and the planar area of each of the first color filter CF1, the second color filter CF2, and the third color filter CF3 may be substantially equal to the planar area of each of the plurality of light-emitting areas EA1, EA2, and EA3.

The second overcoat layer OC2 may be located on the color filter layer CFL. The second overcoat layer OC2 may be directly located on the color filter layer CFL. The second overcoat layer OC2 may be located entirely in the display area DPA, and may have a flat surface. The second overcoat layer OC2 may flatten the step formed by the lower color filter layer CFL. The second overcoat layer OC2 may include a light-transmitting organic material, and may be substantially the same as or similar to the first overcoat layer OC1 described above.

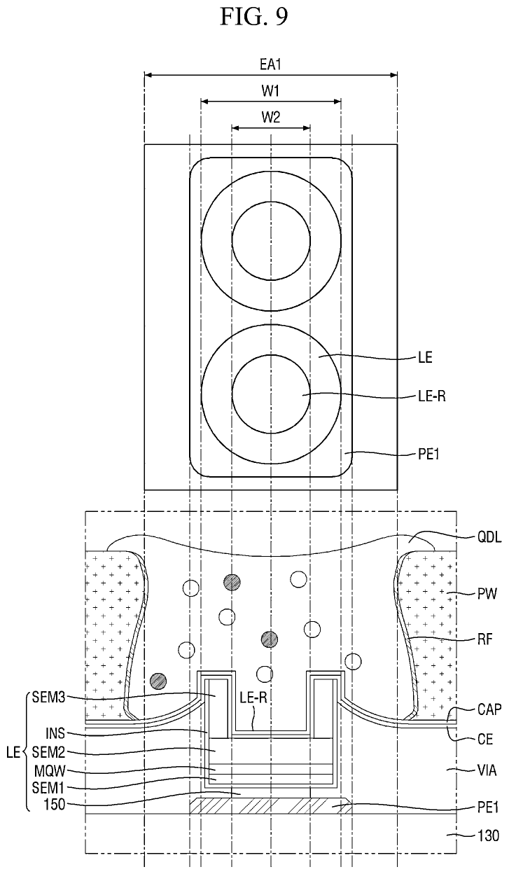

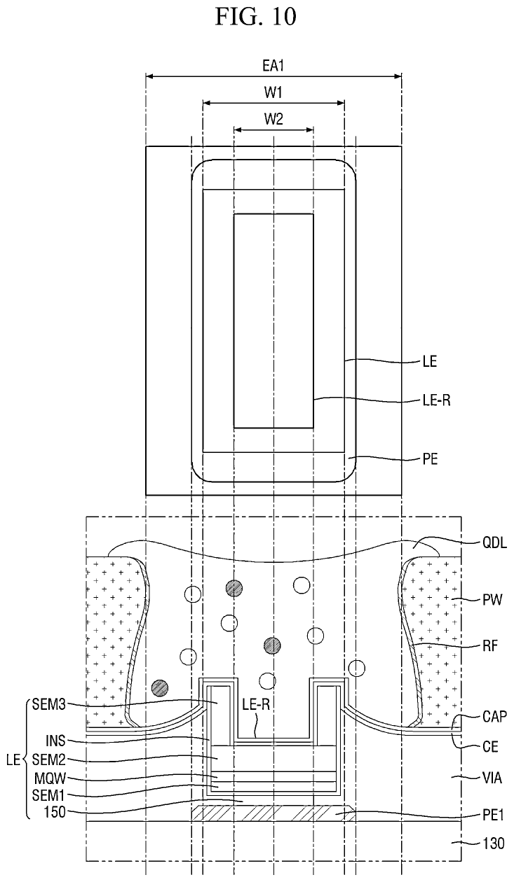

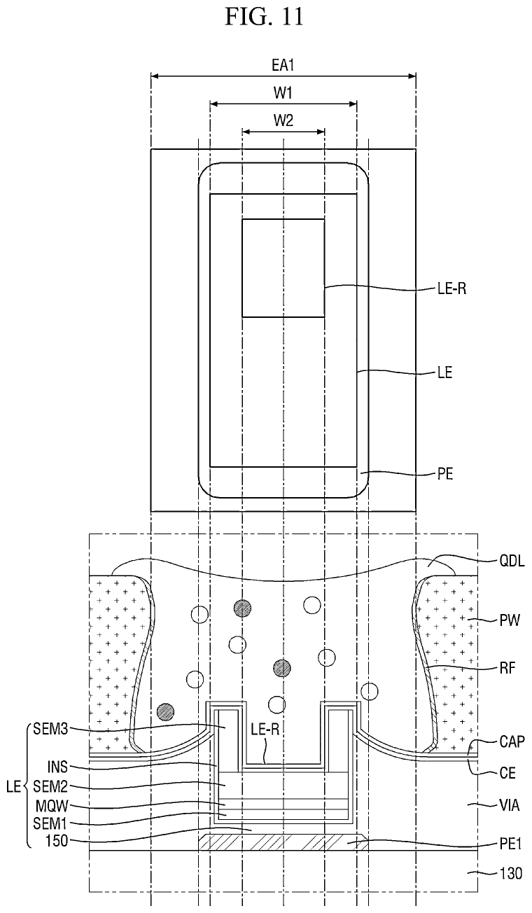

FIG. 7 is an enlarged view schematically illustrating the first light-emitting area described with reference to FIG. 6. FIG. 8 is an enlarged view of a light-emitting element according to one or more embodiments described with reference to FIG. 7. FIG. 9 is a plan view of a pixel electrode and a light-emitting element according to the one or more embodiments described with reference to FIG. 7. FIGS. 10 and 11 are plan views of a pixel electrode and a light-emitting element according to a modified version(s) of the one or more embodiments corresponding to FIG. 9.

Referring to FIGS. 7 to 9, the structure on the first light-emitting area EA1 has been described as an example, but the structure is not limited thereto, and the structures on the second light-emitting area EA2 and the third light-emitting area EA3 may be equally configured.

A connection electrode 150 may be located on each of the plurality of pixel electrodes PE1, PE2, and PE3.

In the following, the light-emitting element LE located on the first pixel electrode PE1 will be described as an example, but the scope is not limited thereto, and the structure of the light-emitting element LE located on the second pixel electrode PE2 and the third pixel electrode PE3 may be similarly configured.

The connection electrode 150 is an electrode that connects the light-emitting element LE and the pixel electrodes PE1, PE2, and PE3, and may include at least one of gold (Au), copper (Cu), tin (Sn), silver (Ag), aluminum (Al), and titanium (Ti).

Although FIG. 8 illustrates the connection electrode 150 in which the light-emitting element LE has a single-sided structure, the present disclosure is not limited thereto. In some cases, the light-emitting element LE may include the connection electrode 150 in which multiple layers are stacked. For example, the connection electrode 150 may include a reflective layer and a connection layer. The reflective layer may serve to reflect light emitted from an active layer MQW of the light-emitting element LE. The reflective layer may be located adjacent to the active layer MQW of the light-emitting element LE. The reflective layer may include a metal material that is conductive, and that has a high light reflectance. The reflective layer may include, for example, aluminum (Al) or silver (Ag), or an alloy thereof. The connection layer may serve to transmit a light-emitting signal from the first pixel electrode PE1 to the light-emitting element LE. The connection layer may be an ohmic connection electrode. However, the connection layer is not limited to this and may be a Schottky connection electrode. The connection layer may be located at the bottom of the light-emitting element LE, and may be located farther from the active layer MQW than the reflective layer. The connection layer may include at least one of gold (Au), copper (Cu), tin (Sn), silver (Ag), aluminum (Al), and titanium (Ti). For example, the connection layer may include a 9:1 alloy, 8:2 alloy, or 7:3 alloy of gold and tin, or may include an alloy of copper, silver, and tin (SAC305).

As shown in FIG. 8, the light-emitting element LE includes a first semiconductor layer SEM1, an electron-blocking layer EBL, an active layer MQW, a superlattice layer SLT, a second semiconductor layer SEM2, and a third semiconductor layer SEM3 in the third direction DR3. The first semiconductor layer SEM1, the electron-blocking layer EBL, the active layer MQW, the superlattice layer SLT, the second semiconductor layer SEM2, and the third semiconductor layer SEM3 may be stacked sequentially in the third direction DR3.

The first semiconductor layer SEM1 may be doped with a first conductivity type dopant, such as Mg, Zn, Ca, or Ba. For example, the first semiconductor layer SEM1 may be p-GaN doped with p-type Mg. The thickness of the first semiconductor layer SEM1 may be about 30 nm to about 200 nm.

The electron-blocking layer EBL may be located on the first semiconductor layer SEM1. The electron-blocking layer EBL may be a layer for suppressing or preventing too many electrons from flowing into the active layer MQW. For example, the electron-blocking layer EBL may be p-AlGaN doped with p-type Mg. A thickness of the electron-blocking layer EBL may be about 10 nm to about 50 nm. The electron-blocking layer EBL may be omitted.

The active layer MQW may be located on the electron-blocking layer EBL. The active layer MQW may emit light by recombining electron-hole pairs according to electrical signals applied through the first semiconductor layer SEM1 and the second semiconductor layer SEM2. The active layer MQW may emit first light having a central wavelength range of about 450 nm to about 495 nm, that is, light in the blue wavelength band.

The active layer MQW may include a material having a single or multi-quantum well structure. When the active layer MQW includes a material having a multi-quantum well structure, it may have a structure in which a plurality of well layers and barrier layers are alternately stacked. In this case, the well layer may be formed of InGaN, and the barrier layer may be formed of GaN or AlGaN but is not limited thereto. The thickness of the well layer may be about 1 nm to about 4 nm, and the thickness of the barrier layer may be about 3 nm to about 10 nm.

Alternatively, the active layer MQW may have a structure in which semiconductor materials having a high energy band gap and semiconductor materials having a low energy band gap are alternately stacked with each other, may include other Group III to V semiconductor materials according to the wavelength range of emitted light. The light emitted from the active layer MQW is not limited to the first light (light in the blue wavelength band), and may emit second light (light in the green wavelength band) or third light (light in the red wavelength band) in some cases. The thickness of the active layer MQW may be about 10 nm to about 25 nm.

The superlattice layer SLT may be located on the active layer MQW. The superlattice layer SLT may be a layer for relieving stress between the second semiconductor layer SEM2 and the active layer MQW. For example, the superlattice layer SLT may be formed of InGaN or GaN. A thickness of the superlattice layer SLT may be about 50 nm to about 200 nm. The superlattice layer SLT may be omitted.

The second semiconductor layer SEM2 may be located on the superlattice layer SLT. The second semiconductor layer SEM2 may be doped with a second conductivity type dopant, such as Si, Ge, Se, or Sn. For example, the second semiconductor layer SEM2 may be n-GaN doped with n-type Si. A thickness of the second semiconductor layer SEM2 may be about 500 nm to about 1 μm.

The third semiconductor layer SEM3 may include the same material as the second semiconductor layer SEM2 but may be a material that is not doped with an n-type or p-type dopant. In one or more embodiments, the third semiconductor layer SEM3 may be at least one of undoped InAlGaN, GaN, AlGaN, InGaN, AlN, and InN, but is not limited thereto.

The third semiconductor layer SEM3 has a recess LE-R that is convex in a downward direction. The recess LE-R may penetrate the third semiconductor layer SEM3, and may expose one surface of the second semiconductor layer SEM2. The inclination angle of the inclined surface of the recess LE-R may be a right angle. The width W2 of the recess LE-R may be about 40% to about 90% or more of the width W1 of the light-emitting element LE. For example, when the width of the light-emitting element LE is about 10 μm, the width of the recess LE-R may be between about 4 μm and about 9 μm, but is not limited thereto. When the recess LE-R is located on the top surface of the second semiconductor layer SEM2 of the light-emitting element LE, the width of the recess LE-R may mean the width of the recess LE-R on the second semiconductor layer SEM2.

As shown in FIG. 9, when the light-emitting element LE is circular, the recess LE-R may also be formed circular. In this case, the light-emitting element LE and the recess LE-R may be concentric circles.

In the one or more other embodiments corresponding to FIG. 9, it is illustrated that two light-emitting elements LE are located on the first pixel electrode PE1, but it is not limited to this, and it is possible to match one light-emitting element LE or three or more light-emitting elements LE.

The light-emitting element LE may further include an element reflective layer RF0 and an insulating layer INS.

The element reflective layer RF0 is located on the lower surface of (e.g., below) the first semiconductor layer SEM1, and may include a metal material with high reflectivity. For example, the element reflective layer RF0 may include aluminum or silver, or an alloy thereof. The element reflective layer RF0 may be omitted.

The insulating layer INS may surround the side surfaces of the light-emitting element LE, for example, the outer peripheral surface. The insulating layer INS may insulate the light-emitting elements LE from other layers. The insulating layer INS may be directly located on the outer peripheral surface of the first semiconductor layer SEM1, the active layer MQW, the second semiconductor layer SEM2, and the third semiconductor layer SEM3 to surround them (e.g., in plan view). In one or more embodiments, the insulating layer INS may surround the entire outer peripheral surface of the first semiconductor layer SEM1, the active layer MQW, the second semiconductor layer SEM2, and the third semiconductor layer SEM3. The insulating layer INS may be formed to cover the element reflective layer RF0 of the light-emitting element LE, but may include/define an opening. The element reflective layer RF0 and the connection electrode 150 may be in contact through the opening in the insulating layer INS formed on/below the element reflective layer RF0.

In another modified example, the light-emitting element LE may include a multi-layer insulating layer INS. Further, the element reflective layer RF0 may be located between the multi-layer insulating layer INS, and may be formed to surround the light-emitting element LE.

As shown in FIGS. 10 and 11, the light-emitting element LE may have a hexahedral shape. For example, the light-emitting element LE may have a size of about 10 μm×25 μm. When the planar shape of the light-emitting element LE is rectangular, the planar shape of the recess LE-R may also be rectangular. The length of the recess LE-R in plan view may be proportional to the length of the light-emitting element LE in plan view, but is not limited thereto. The planar shape of the recess LE-R may resemble the planar shape of the light-emitting element LE, but is not limited thereto. As shown in FIG. 11, the planar shape of the light-emitting element LE and the planar shape of the recess LE-R may be different from each other.

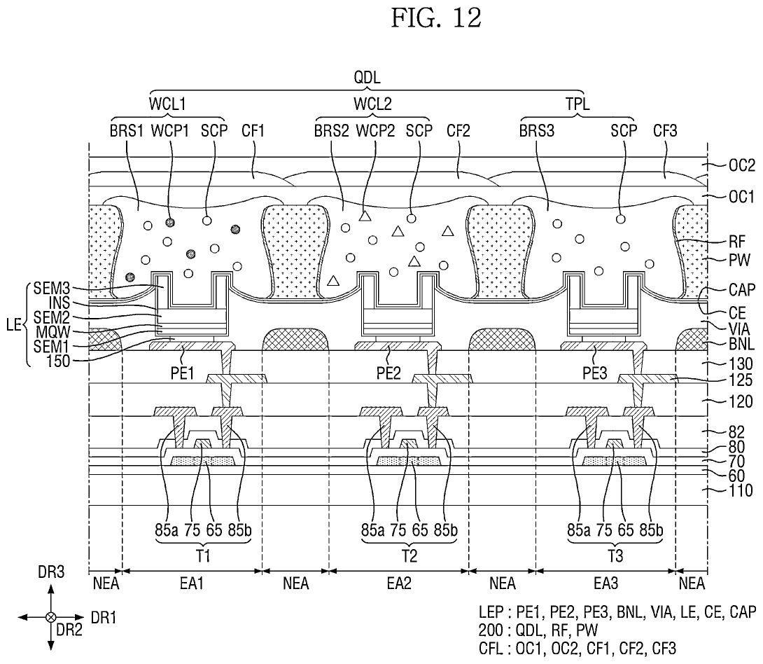

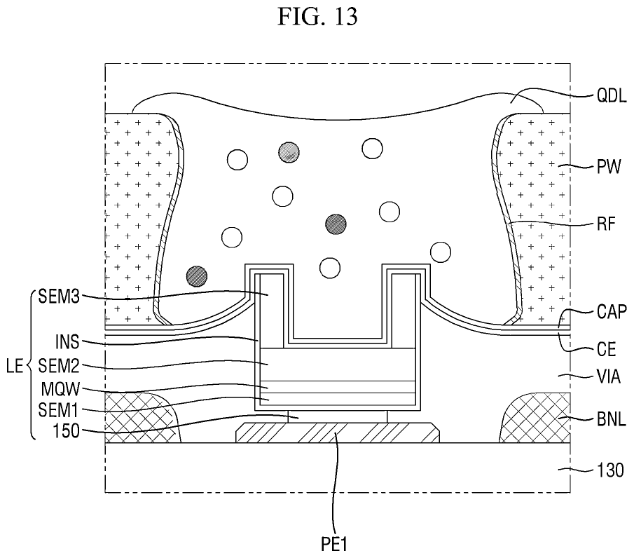

FIG. 12 is a cross-sectional view schematically illustrating a display device according to one or more other embodiments. FIG. 13 is an enlarged view schematically illustrating the first light-emitting area described with reference to FIG. 12.

Referring to FIGS. 12 and 13, the embodiments of FIGS. 12 and 13 differs from the embodiments of FIGS. 6 to 10 described above in that a bank BNL is located on the second planarization layer 130 to define the first light-emitting area EA1.

Hereinafter, descriptions overlapping with the above-described embodiments will be omitted and differences will be described.

The bank BNL may be formed to compartmentalize the pixel electrodes PE1, PE2, and PE3 on the second planarization layer 130 to define the light-emitting areas EA1, EA2 and EA3. The bank BNL may cover the edges of the pixel electrodes PE1, PE2, and PE3. The bank BNL may be formed of an organic material, such as an acrylic resin, an epoxy resin, a phenolic resin, a polyamide resin, a polyimide resin, or the like.

The via layer VIA may be located on the bank BNL and the pixel electrodes PE1, PE2, and PE3. The via layer VIA covers the bank BNL and the pixel electrodes PE1, PE2, and PE3, and may flatten the lower step so that the common electrode CE described later may be formed.

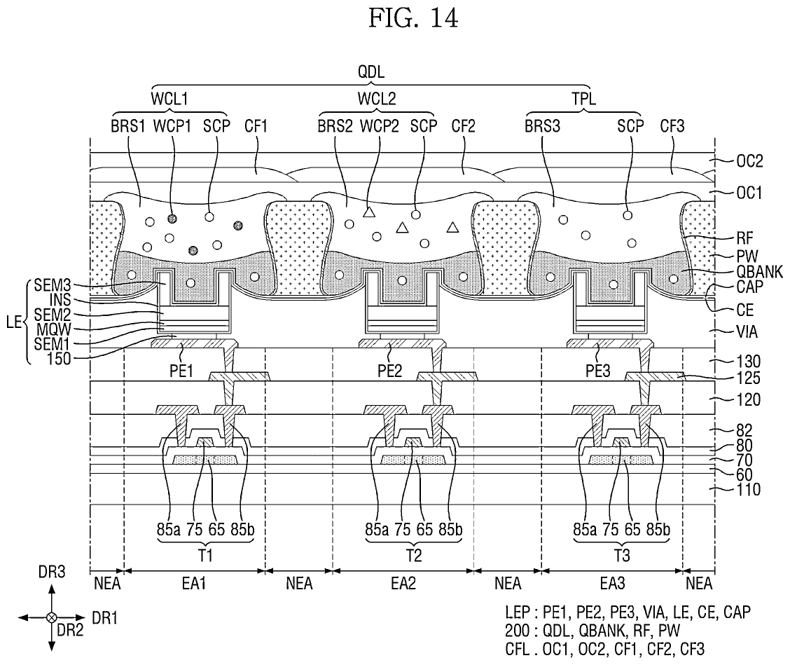

FIG. 14 is a cross-sectional view schematically illustrating a display device according to one or more other embodiments. FIG. 15 is an enlarged view schematically illustrating the first light-emitting area described with reference to FIG. 14.

The embodiments of FIGS. 14 and 15 differ from the one or more other embodiments corresponding to FIGS. 6 to 10 in that the display device 10 further includes the scattering layer QBANK. Hereinafter, descriptions overlapping with the above-described embodiments will be omitted, and differences will be described.

Referring to FIGS. 14 and 15, the wavelength control unit 200 may include the partition wall unit PW, the scattering layer QBANK, the wavelength conversion layer QDL, and the reflective layer RF.

The partition wall unit PW is located on the capping layer CPA, and may compartmentalize a plurality of light-emitting areas EA1, EA2, and EA3. The partition wall unit PW is arranged to extend in the first direction DR1 and the second direction DR2, and may be formed in a grid-like pattern throughout the display area DA. Furthermore, the partition wall unit PW may not overlap with the plurality of light-emitting areas EA1, EA2, and EA3, and may overlap with the non-emitting area NEA.

The reflective layer RF may reflect light emitted from the light-emitting elements LE and traveling laterally upward (e.g., in the third direction DR3). The reflective layer RF may include a metal material with high light reflectance. For example, the reflective layer RF may include aluminum or silver, or an alloy thereof.

The scattering layer QBANK and the wavelength conversion layer QDL may be sequentially located in the space formed by the partition wall unit PW. The scattering layer QBANK may scatter the light of the light-emitting element LE, and may reduce or prevent heat generated by the light-emitting element LE from being directly transferred to the wavelength conversion layer QDL. The scattering layer QBANK may be located on the capping layer CAP. The scattering layer QBANK may be located between the light-emitting element LE and the wavelength conversion layer QDL, and may reduce or prevent deterioration of the wavelength conversion layer QDL due to heat generated from the light-emitting element LE.

The scattering layer QBANK may include a base resin BRS0, and the scatterer SCP dispersed in the base resin BRS0. The base resin BRS0 may include a light-transmitting organic material. For example, the base resin BRS0 may include epoxy resin, acrylic resin, cardo resin, or imide resin.

The scatterer SCP may scatter the light of the light-emitting element LE in a random direction. The scatterer SCP may have a different refractive index from the base resin BRS0, and may form an optical interface with the base resin BRS0. For example, the scatterer SCP may be a light-scattering particle. The scatterer SCP is not particularly limited to any material capable of scattering at least a portion of the transmitted light, but may be, for example, a metal oxide particle or an organic particle. Examples of the metal oxide include titanium oxide (TiO₂), zirconium oxide (ZrO₂), aluminum oxide (Al₂O₃), indium oxide (In₂O₃), zinc oxide (ZnO), or tin oxide (SnO₂), and examples of organic particle materials include acrylic resins or urethane resins. The scatterer SCP may scatter light in a random direction regardless of the incident direction of the incident light without substantially converting the wavelength of the light.

The scattering layer QBANK may be located in the recess LE-R of the light-emitting element LE. The wavelength conversion layer QDL may be located on the scattering layer QBANK. The wavelength conversion layer QDL may convert or shift the peak wavelength of incident light into light of another corresponding peak wavelength, and may emit the light. The wavelength conversion layer QDL may convert the blue first light emitted from the light-emitting element LE into red second light, may convert the blue first light into green third light, or may transmit the blue first light as it is.

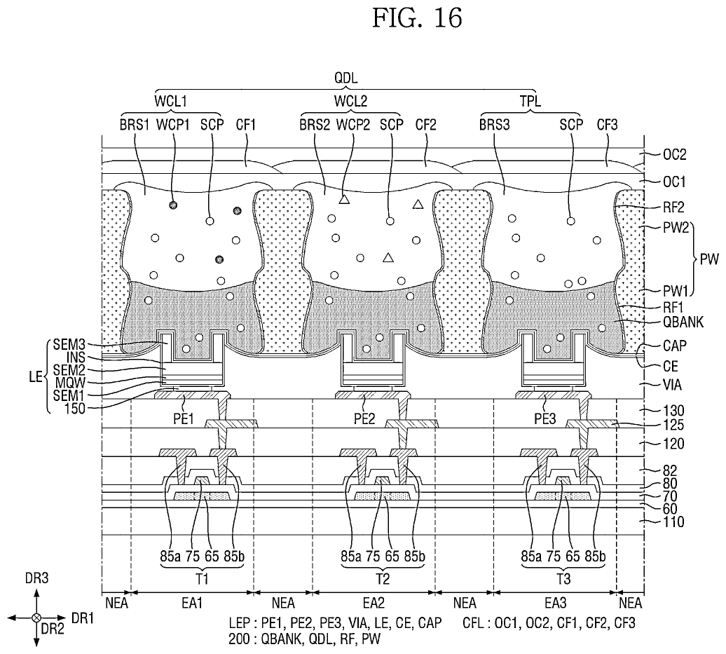

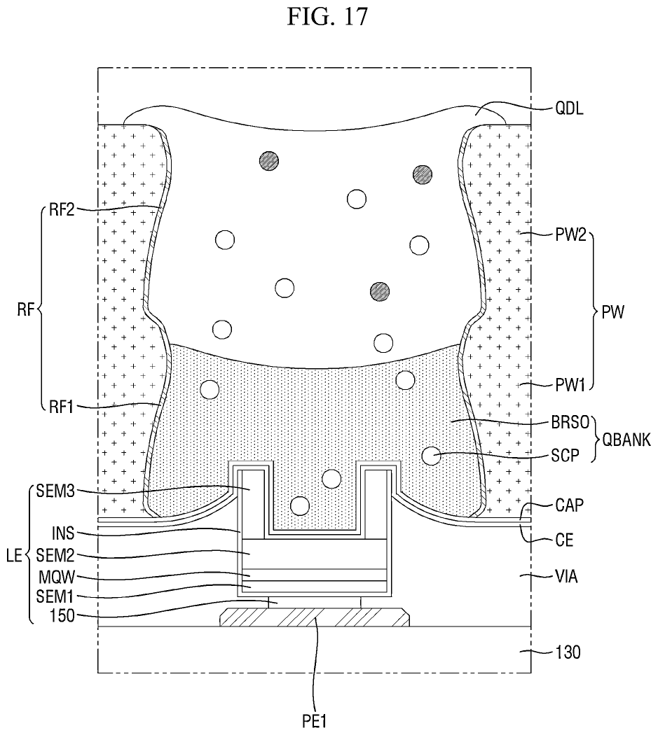

FIG. 16 is a cross-sectional view schematically illustrating a display device according to one or more other embodiments. FIG. 17 is an enlarged view schematically illustrating the first light-emitting area described with reference to FIG. 16.

The embodiments of FIGS. 16 and 17 differ from the embodiments of FIGS. 14 and 15 in that the partition wall unit PW includes a first partition wall PW1 and a second partition wall PW2. Hereinafter, descriptions overlapping with the above-described embodiments will be omitted and differences will be described.

The partition wall unit PW may serve to provide a space for the wavelength conversion layer QDL to be formed. The partition wall unit PW may be arranged to extend in the first direction DR1 and the second direction DR2, and may be in a grid-like pattern throughout the display area DPA. Furthermore, the partition wall unit PW may not overlap with the plurality of light-emitting areas EA1, EA2, and EA3, and may overlap with the non-emitting area NEA.

The partition wall unit PW may be relatively thick, including a two-layer structure of the first partition wall PW1 and the second partition wall PW2, to provide a space in which the wavelength conversion layer QDL is formed. To this end, the partition wall unit PW may include the first partition wall PW1, and the second partition wall PW2 located on the first partition wall PW1.

The second partition wall PW2 may be located on the first partition wall PW1, while overlapping with the first partition wall PW1.

The first partition wall PW1 and the second partition wall PW2 may include a negative photosensitive material, and may have an inverted tapered shape. The first partition wall PW1 and the second partition wall PW2 may include an organic insulating material to be thick. The organic insulating material may include, for example, epoxy resin, acrylic resin, cardo resin, or imide resin. The second partition wall PW2 may be located on the first partition wall PW1 while overlapping with the first partition wall PW1.

The first partition wall PW1 and the second partition wall PW2 may block the transmission of light in the non-emitting area NEA. The first partition wall PW1 and the second partition wall PW2 may further include the light-blocking material, and may include a dye or pigment having light-blocking properties. For example, the first partition wall PW1 and the second partition wall PW2 may be a black matrix. External light incident from the outside of the display device 10 may cause a problem that distorts the color gamut of the wavelength control unit 200. According to one or more embodiments, the first partition wall PW1 and the second partition wall PW2 including the light-blocking material are located in the wavelength control unit 200 so that at least a portion of external light is absorbed by a light-blocking member BK. Therefore, color distortion caused by external light reflection may be reduced. Furthermore, the first partition wall PW1 and the second partition wall PW2 including the light-blocking material may reduce or prevent color mixing from occurring due to light intrusion between adjacent light-emitting areas, thereby further improving the color reproduction rate.

The height of the partition wall unit PW may be about 10 μm to about 15 μm. The height of the first partition wall PW1 may be about 7 μm to about 9 μm. Further, the height of the second partition wall PW2 may be about 5 μm to about 7 μm. For example, the height of the first partition wall PW1 may be about 8 μm, and the height of the second partition wall PW2 may be about 6 μm.

The reflective layer RF may be located on the inner surface of the space formed by the partition wall unit PW. The reflective layer RF may not overlap the light-emitting areas EA1, EA2, and EA3, and may overlap the non-emitting area NEA. The reflective layer RF may include the first reflective layer RF1 and the second reflective layer RF2. The first reflective layer RF1 may surround the side of the first partition wall PW1, and the second reflective layer RF2 may surround the side of the second partition wall PW2.

The reflective layer RF may reflect light emitted from the light-emitting elements LE and traveling laterally upward (e.g., in the third direction DR3). The reflective layer RF may include a metal material with high light reflectance. For example, the reflective layer RF may include aluminum or silver, or an alloy thereof.

The scattering layer QBANK may be located in the space formed by the first partition wall PW1. The thickness of the scattering layer QBANK may be less than the thickness of the first partition wall PW1.

The wavelength conversion layer QDL may be further located on the scattering layer QBANK. The wavelength conversion layer QDL may be surrounded by the first partition wall PW1 and the second partition wall PW2. The thickness of the wavelength conversion layer QDL may be thicker than the thickness of the scattering layer QBANK. The thickness of the wavelength conversion layer QDL may be thicker than the thickness of the second partition wall PW2.

The scattering layer QBANK may be located in the recess LE-R of the light-emitting element LE.

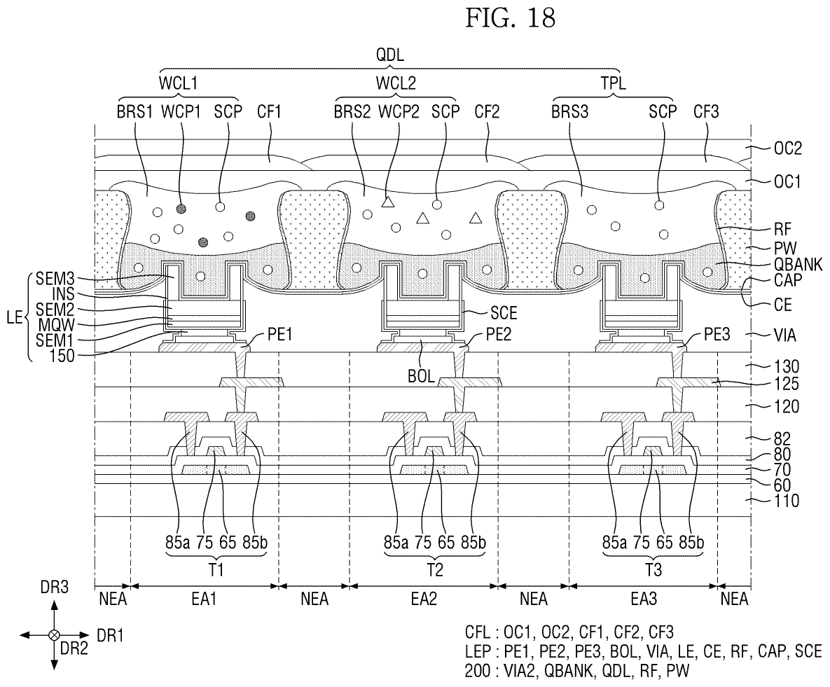

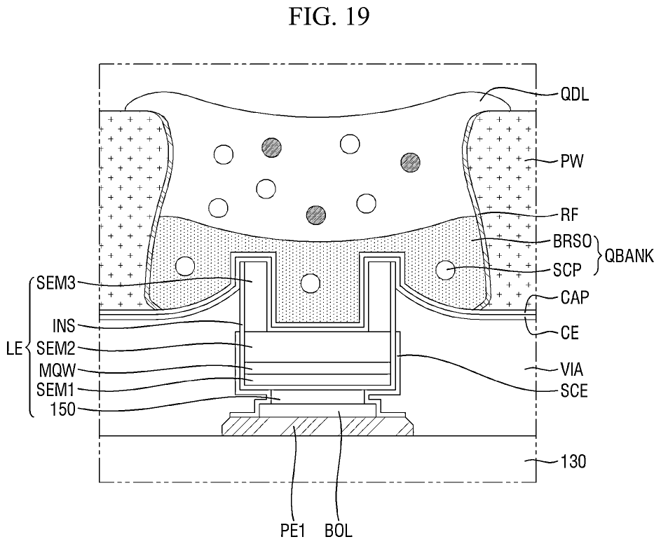

FIG. 18 is a cross-sectional view schematically illustrating a display device according to one or more other embodiments. FIG. 19 is an enlarged view schematically illustrating the first light-emitting area described with reference to FIG. 18.

The embodiments of FIGS. 18 and 19 differ from the embodiments corresponding to FIGS. 14 and 15 in that the light-emitting element LE and the pixel electrodes PE1, PE2, and PE3 are side bonded. Hereinafter, descriptions overlapping with the above-described embodiments will not be repeated, and differences will be described.

Referring to FIGS. 18 and 19, the light-emitting element unit LEP may include a plurality of pixel electrodes PE1, PE2, and PE3, an organic pattern layer BOL, a plurality of light-emitting elements LE, a sub-connection electrode SCE, a via layer VIA, and a common electrode CE. Also, the light-emitting element unit LEP may further include the capping layer CAP covering the common electrode CE.

The organic pattern layer BOL is located on the pixel electrodes PE1, PE2, and PE3. The organic pattern layer BOL may expose at least a portion of the pixel electrodes PE1, PE2, and PE3.

The organic pattern layer BOL may overlap the light-emitting element LE. The light-emitting element LE may be located on the organic pattern layer BOL. The connection electrode 150 may be further located between the organic pattern layer BOL and the light-emitting element LE. The connection electrode 150 directly contacts the lower part of the element reflective layer RF0 of the light-emitting element LE.

The organic pattern layer BOL, the connection electrode 150, and the light-emitting element LE may be sequentially located on the pixel electrodes PE1, PE2, and PE3. The sub-connection electrode SCE is formed along the side of the light-emitting element LE to the side of the connection electrode 150, to the side of the organic pattern layer BOL, and to the top surface of the pixel electrodes PE1, PE2, and PE3 by a deposition method, such as sputtering. The connection electrode 150 and the pixel electrodes PE1, PE2, and PE3 are electrically connected by the sub-connection electrode SCE.

As shown in FIGS. 18 and 19, the sides of the pixel electrodes PE1, PE2, and PE3, the organic pattern layer BOL, the connection electrode 150, and the light-emitting element LE are formed to have a step difference from each other, but is not limited thereto.

In another modified example, at least two of the sides of the organic pattern layer BOL, the connection electrode 150, and the light-emitting element LE may be aligned with each other. For example, the sides of the organic pattern layer BOL and the connection electrode 150 may be aligned with each other. In another example, the side surfaces of the connection electrode 150 and the light-emitting element LE may be aligned with each other. In another example, the sides of the organic pattern layer BOL, the connection electrode 150, and the light-emitting element LE may be aligned with each other.

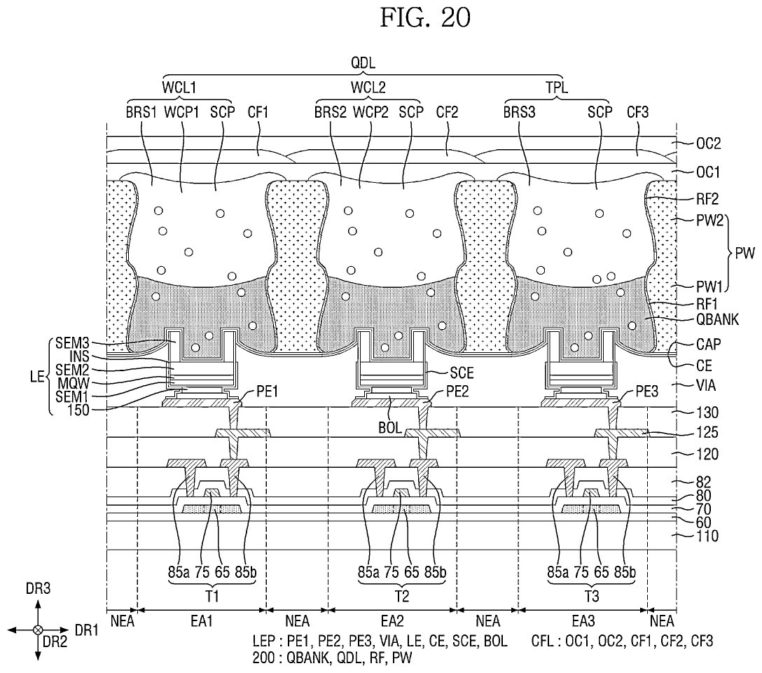

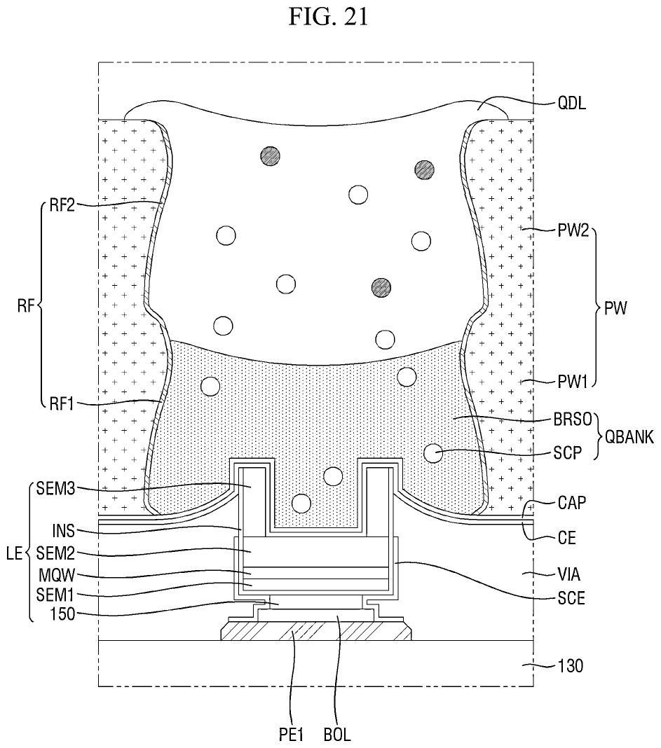

FIG. 20 is a cross-sectional view schematically illustrating a display device according to one or more other embodiments. FIG. 21 is an enlarged view schematically illustrating the first light-emitting area described with reference to FIG. 20.

The embodiments of FIGS. 20 and 21 differ from the embodiments of FIGS. 18 and 19 in that the partition wall unit PW includes the first partition wall PW1 and the second partition wall PW2. Hereinafter, descriptions overlapping with the above-described embodiments will be omitted and differences will be described.

Referring to FIGS. 20 and 21, the partition wall unit PW may include the first partition wall PW1 and the second partition wall PW2 located on the first partition wall PW1. Because the structure of the two-layered partition wall unit PW has been described with reference to FIGS. 16 and 17, detailed description will be omitted.

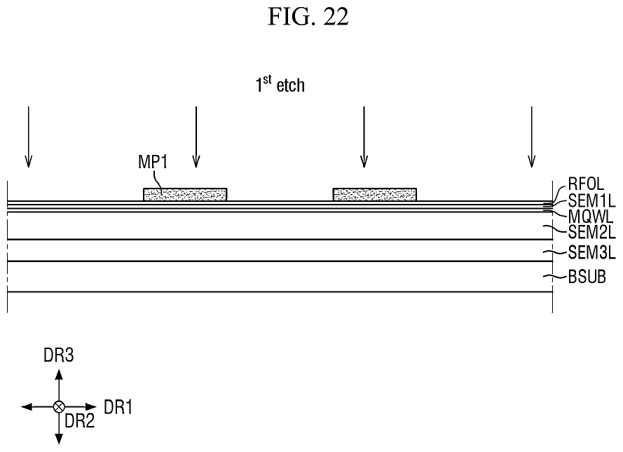

FIGS. 22 to 38 are drawings to illustrate a method of manufacturing a display device according to one or more embodiments.

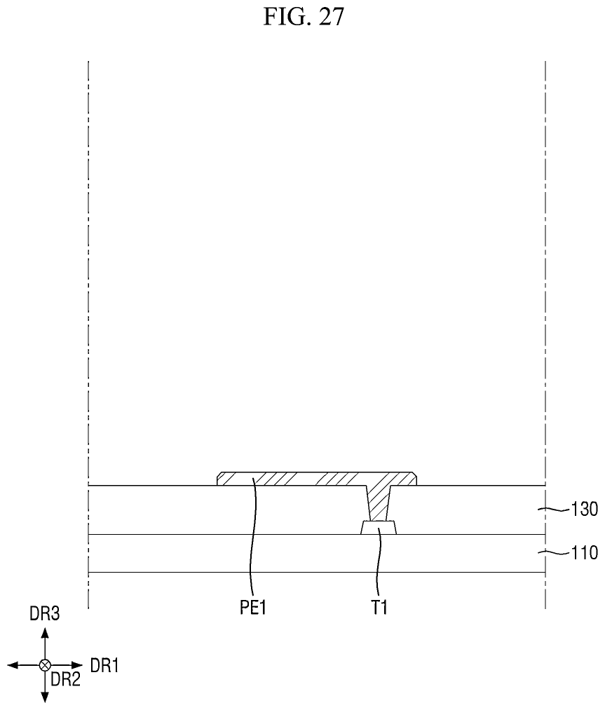

FIGS. 22 to 26 respectively illustrate the structure of the layers of the display device 10 in the order of formation in cross-sectional views. FIGS. 27 to 38 illustrate the manufacturing process of the light-emitting element unit LEP, which may be roughly corresponding to the cross-sectional views of FIGS. 6 to 8 respectively. Also, the first light-emitting area EA1 of the display device 10 is highlighted below.

Referring to FIGS. 22 to 26, a plurality of light-emitting elements LE are formed on the base substrate BSUB.

For example, as shown in FIG. 22, a plurality of semiconductor material layers SEM3L, SEM2L, MQWL, and SEM1L are formed on the base substrate BSUB.

The base substrate BSUB may be a sapphire substrate (Al₂O₃) or a silicon wafer including silicon. However, it is not limited thereto, and in one or more embodiments, a case where the base substrate BSUB is a sapphire substrate will be described as an example.

The plurality of semiconductor material layers SEM3L, SEM2L, MQWL, and SEM1L are formed on the base substrate BSUB. The plurality of semiconductor material layers grown by the epitaxial method may be formed by growing a seed crystal. Methods for forming semiconductor material layers include electron beam deposition, physical vapor deposition (PVD), chemical vapor deposition (CVD), and plasma laser deposition (PLD), dual-type thermal evaporation, sputtering, metal organic chemical vapor deposition (MOCVD), and/or the like, and preferably formed by metal organic chemical vapor deposition (MOCVD). However, it is not limited thereto.

A precursor material for forming the plurality of semiconductor material layers is not particularly limited within the range that may be conventionally selected for forming the subject material. In one example, the precursor material may be a metal precursor including an alkyl group, such as a methyl or ethyl group. For example, it may be a compound, such as trimethyl gallium (Ga(CH₃)₃), trimethyl aluminum (Al(CH₃)₃), triethyl phosphate ((C₂H₅)₃PO₄) but are not limited thereto.

For example, a third semiconductor material layer SEM3L is formed on the base substrate BSUB. While the drawings illustrate the third semiconductor material layer SEM3L being further stacked, it is not limited to this, and a plurality of layers may be formed. The third semiconductor material layer SEM3L may reduce a lattice constant difference between a second semiconductor material layer SEM2L and the base substrate BSUB. For example, the third semiconductor material layer SEM3L may include an undoped semiconductor, which may be an n-type or p-type undoped material. In one or more embodiments, the third semiconductor material layer SEM3L may be at least one of undoped InAlGaN, GaN, AlGaN, InGaN, AlN, and InN but is not limited thereto.

The second semiconductor material layer SEM2L, the active material layer MQWL, and the first semiconductor material layer SEM1L are sequentially formed on the third semiconductor material layer SEM3L by using the above-described method.

Next, a reflective material layer RFOL is formed on the plurality of semiconductor material layers SEM3L, SEM2L, MQWL, and SEM1L. The reflective material layer RFOL may be formed to cover all the plurality of semiconductor material layers SEM3L, SEM2L, MQWL, and SEM1L. The reflective material layer RFOL may include aluminum (Al) or silver (Ag) or may be an alloy thereof.

Then, the plurality of semiconductor material layers SEM3L, SEM2L, MQWL, and SEM1L and the reflective material layers RFOL may be etched.

For example, a plurality of first mask patterns MP1 are formed on the reflective material layer RFOL. The first mask pattern MP1 may be a hard mask including an inorganic material or a photoresist mask including an organic material. The first mask pattern MP1 reduces or prevents the likelihood of the lower plurality of semiconductor material layers SEM3L, SEM2L, MQWL, and SEM1L and the reflective material layer RFOL being etched. Next, a portion of the plurality of semiconductor material layers SEM3L, SEM2L, MQWL, SEM1L and the reflective material layer RFOL are etched (1^{st} etch) using the plurality of first mask patterns MP1 as a mask.

The plurality of semiconductor material layers SEM3L, SEM2L, MQWL, and SEM1L and the reflective material layer RFOL that are non-overlapping with the first mask pattern MP1 are etched and removed, and the portions that are not etched overlapping with the first mask pattern MP1 may be formed into the plurality of light-emitting elements LE on the base substrate BSUB.

The plurality of semiconductor material layers SEM3L, SEM2L, MQWL, and SEM1L and the reflective material layers RFOL may be etched by conventional methods. For example, the process of etching the plurality of semiconductor material layers SEM3L, SEM2L, MQWL, and SEM1L and the reflective material layers RFOL may be performed by dry etching, wet etching, reactive ion etching (RIE), deep reactive ion etching (DRIE), inductively coupled plasma reactive ion etching (ICP-RIE), and/or the like. In the case of dry etching methods, anisotropic etching is possible, which may be suitable for vertical etching. When utilizing the etching method described above, the etchant may be Cl₂ or O₂. However, it is not limited thereto.

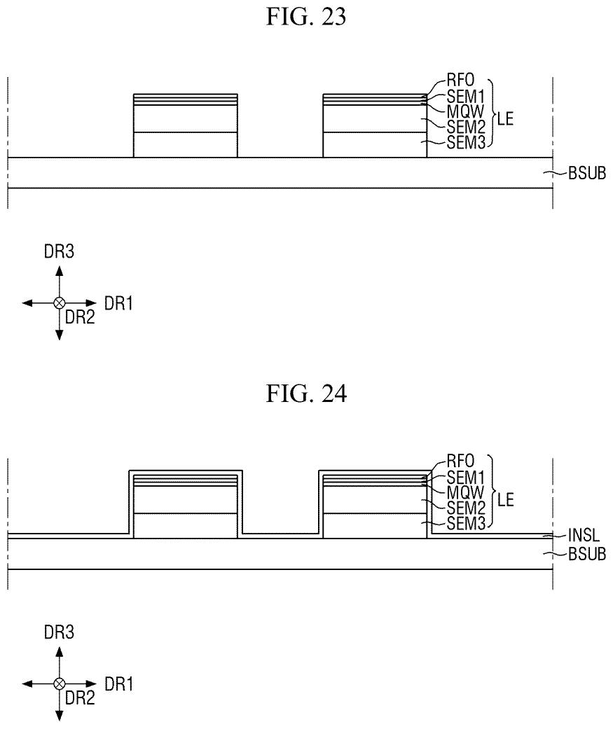

As shown in FIG. 23, a plurality of semiconductor material layers SEM3L, SEM2L, MQWL, and SEM1L and the reflective material layers RFOL overlapping the first mask pattern MP1 are not etched, and are formed into the plurality of light-emitting elements LE. Thus, the plurality of light-emitting elements LE are formed including a third semiconductor layer SEM3, the second semiconductor layer SEM2, the active layer MQW, the first semiconductor layer SEM1, and the element reflective layer RF0.

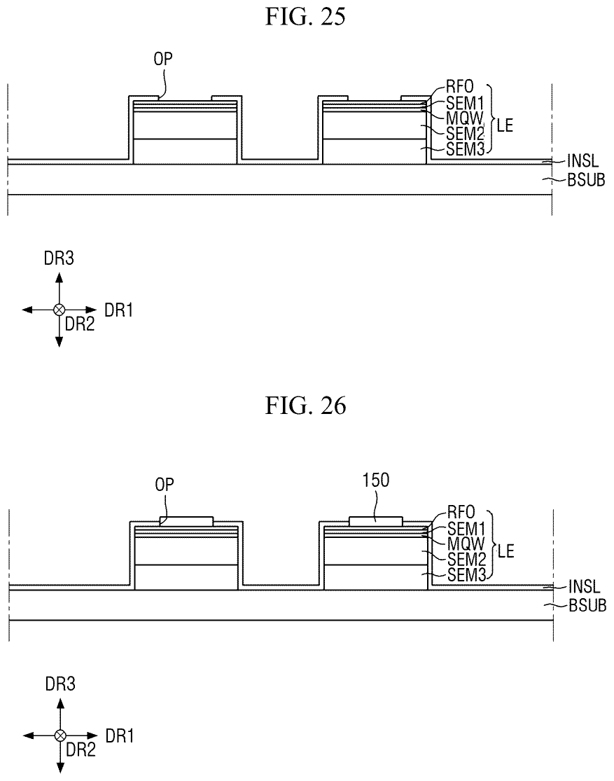

Referring to FIGS. 24 and 25, an element-insulating layer INSL having/defining an opening OP is formed on the base substrate BSUB (hereinafter, for convenience of description, may also be referred to as the growth substrate BSUB) on which the light-emitting element LE is formed.

For example, the element-insulating layer INSL is formed on the outer surfaces of the plurality of light-emitting elements LE. The element-insulating layer INSL may be formed on the entire surface of the base substrate BSUB, and may be formed not only on the light-emitting element LE, but also on the top surface of the base substrate BSUB exposed by the light-emitting element LE.

Then, a second etch (2^{nd} etch) is performed to partially remove the element-insulating layer INSL to form the first insulating layer INS1 having the opening on the top surface of the light-emitting element LE.

For example, the second etch (2^{nd} etch) may be performed in which the element-insulating layer INSL is partially removed such that the element-insulating layer INSL exposes the top surface of the light-emitting element LE while surrounding the sides of the light-emitting element LE. For example, in this process, the element-insulating layer INSL may be removed to expose at least a portion of the top surface of the element reflective layer RF0 of the light-emitting element LE. The process of partially removing the element-insulating layer INSL may be performed by a mask process.

Referring to FIG. 26, the light-emitting element LE may be formed by forming the connection electrode 150 in the opening OP.

For example, the connection electrode 150 may be formed by stacking the connection electrode material layer on the base substrate BSUB, and then etching it through an etching process to form the connection electrode 150 located in the opening OP of the light-emitting element LE. The connection electrode 150 may be formed to protrude above the foot and the light-emitting element LE. The connection electrode material layer is formed of a conductive material and may include at least one of gold (Au), copper (Cu), tin (Sn), silver (Ag), aluminum (Al), and titanium (Ti). For example, the connection electrode material layer may include a 9:1 alloy, an 8:2 alloy, or a 7:3 alloy of gold and tin, or may include an alloy of copper, silver, and tin (SAC305).

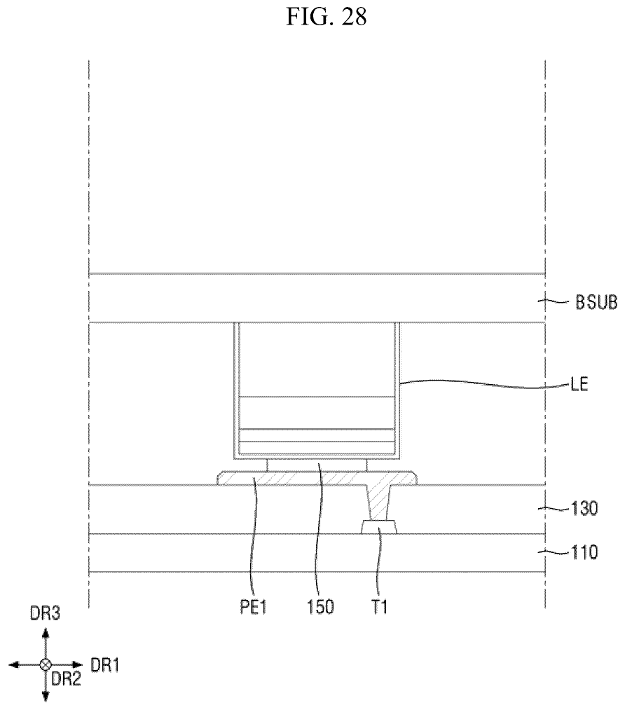

Referring to FIGS. 27 and 28, a growth substrate BSUB is bonded to the substrate 110, and the light-emitting element LE is bonded to the first pixel electrode PE1. In one or more embodiments, the growth substrate BSUB is illustrated as being bonded to the substrate 110, but the light-emitting element LE grown on the growth substrate BSUB may be bonded to the substrate 110 after being transferred to a temporary substrate, a relay substrate, a transfer film, or the like one or more times.

First, referring to FIG. 27, a substrate 110 including the second planarization layer 130 and the first pixel electrode PE1 is prepared.

The growth substrate BSUB is aligned on the substrate 110. The light-emitting element LE grown on the growth substrate BSUB is aligned to be placed on the first pixel electrode PE1 of the substrate 110. The width of the first pixel electrode PE1 may be wider than the width of the light-emitting element LE (e.g., in plan view). In this case, the light-emitting element LE may be located within the first pixel electrode PE1.

Next, the substrate 110 and the growth substrate BSUB are bonded. For example, the connection electrode 150 of the light-emitting element LE formed on the growth substrate BSUB is contacted with the first pixel electrodes PE1 of the substrate 110. At this time, the connection electrode 150 of the light-emitting element LE is in contact with the first pixel electrodes PE1. Then, the substrate 110 and the growth substrate BSUB are bonded by melting the connection electrodes 150 of the light-emitting elements LE and the first pixel electrodes PE1. At this time, the plurality of light-emitting elements LE are attached to the top surfaces of the first pixel electrodes PE1.

As for a melt bonding, a laser may be irradiated onto the first pixel electrodes PE1 from the top of the growth substrate BSUB. The laser-irradiated first pixel electrodes PE1 may conduct relatively high heat from the laser to bond the interface of the connection electrode 150 of the light-emitting element LE and the first pixel electrodes PE1. For example, the first pixel electrodes PE1 may include copper (Cu), which has suitable thermal conductivity, and may have suitable adhesion properties with the connection electrode 150 of the light-emitting element LE. As a source of the laser used for the melt bonding, a YAG may be utilized.

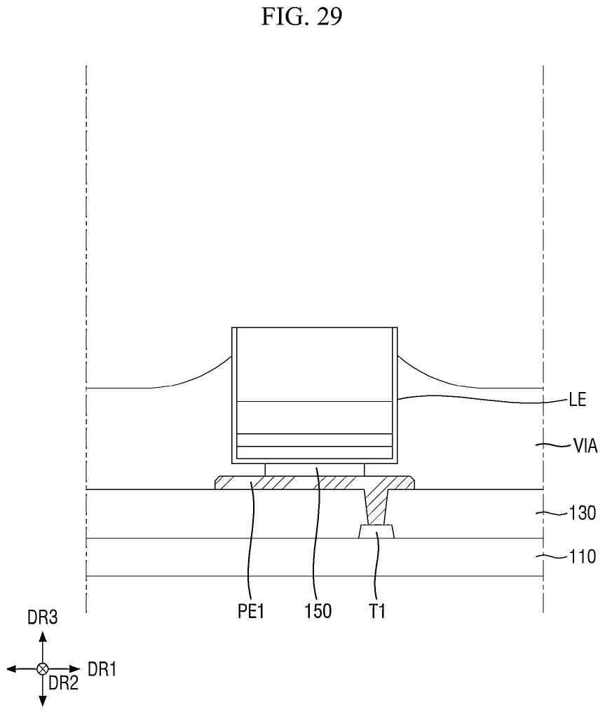

Next, referring to FIG. 29, the growth substrate BSUB is separated from the plurality of light-emitting elements LE.

For example, the growth substrate BSUB is separated from the light-emitting element LE. The growth substrate BSUB may be separated by a laser lift-off (LLO) process. Because the laser lift-off process has been described above, a repeated description will be omitted. The growth substrate BSUB may be separated from the light-emitting element LE by irradiating the growth substrate BSUB with a laser.

The via layer VIA is formed on the substrate 110 on which the light-emitting elements LE are formed.

For example, the via layer VIA may be formed on the first pixel electrode PE1. The via layer VIA may be applied using a solution process, such as spin coating, inkjet printing, or the like. The via layer VIA may be lower than the height of the light-emitting element LE. For example, the top surface of the light-emitting element LE may be exposed through the via layer VIA.

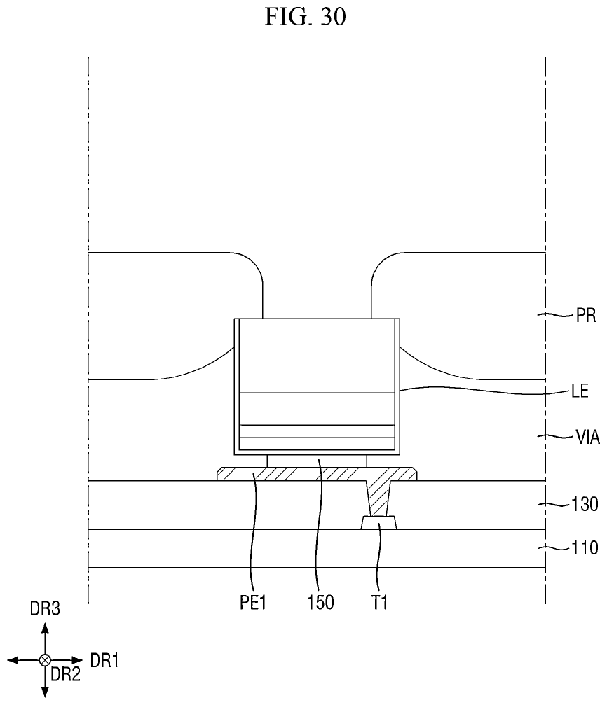

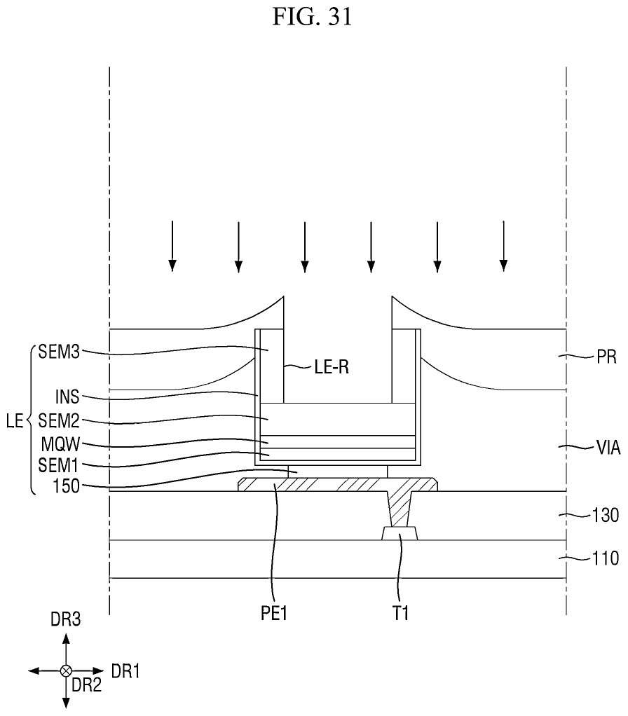

Next, referring to FIGS. 30 and 31, a downwardly convex recess LE-R is formed on the top surface of the light-emitting element LE using a photoresist pattern PR surrounding the border of the light-emitting element LE and the via layer VIA. Here, convex downward means that the center is located further down.

For example, the third semiconductor layer SEM3 is etched using the photoresist pattern PR as a mask. The recess LE-R has an inclined surface of approximately 90 degrees toward the top, and the second semiconductor layer SEM2 may be exposed by the recess LE-R.

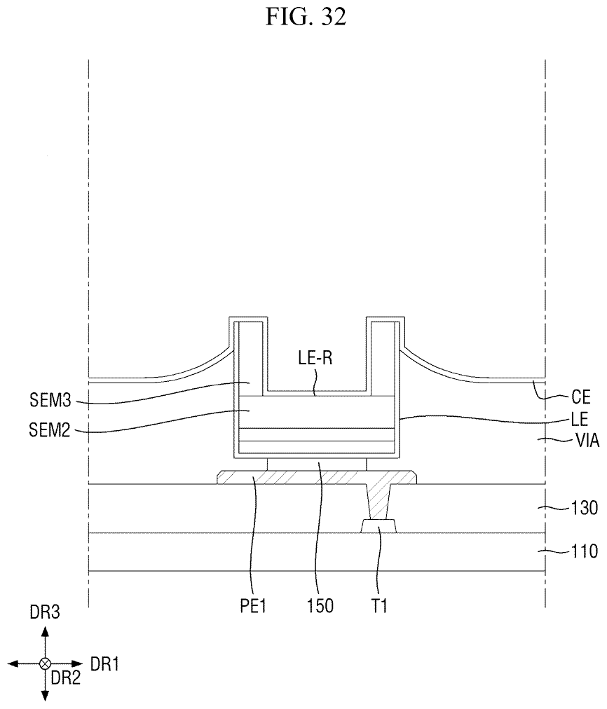

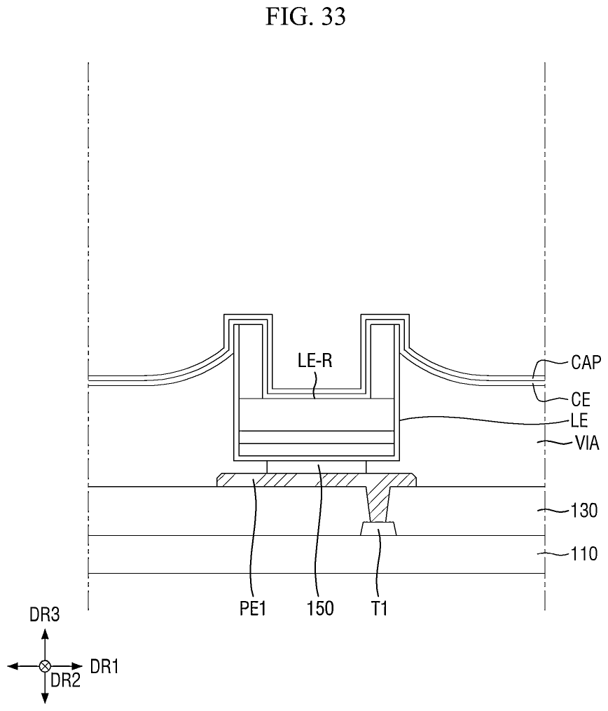

Next, referring to FIGS. 32 and 33, the common electrode CE and the capping layer CAP are formed on the light-emitting element LE.

The common electrode CE is continuously formed throughout the display area. The common electrode CE covers the via layer VIA, the insulating layer INS, and the light-emitting element LE and is in direct contact with them. The common electrode CE is formed by directly contacting the third semiconductor layer SEM3 of the light-emitting element LE as well as the top surface of the second semiconductor layer SEM2 along the recess LE-R. The capping layer CAP may be formed on the entire surface of the substrate 110 to cover the common electrode CE. Accordingly, the capping layer CAP may be formed along the side and bottom surfaces of the recess LE-R of the light-emitting element LE on the common electrode CE.

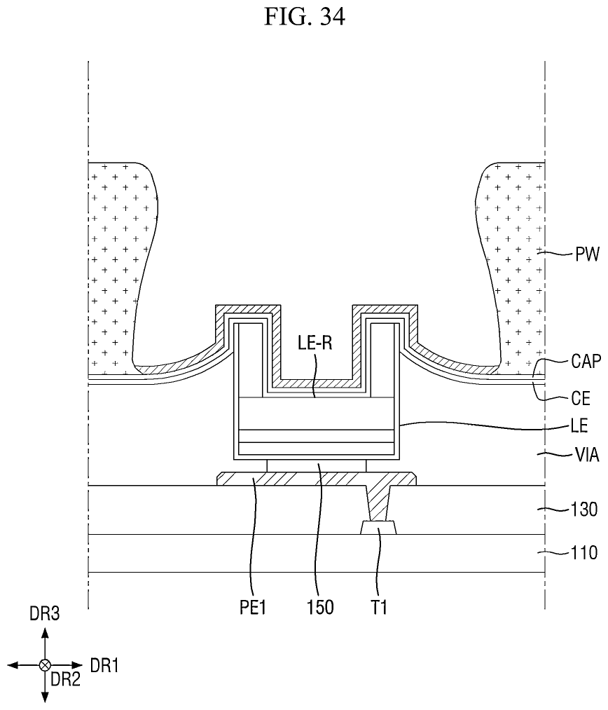

Next, referring to FIG. 34, the partition wall unit PW is formed on the capping layer CAP.

For example, the partition wall unit PW is formed on the capping layer CAP using a negative photoresist. Because the portion of the negative photoresist that does not receive light is dissolved, the partition wall unit PW may be formed in an inverted tapered shape with the width narrowing downward.

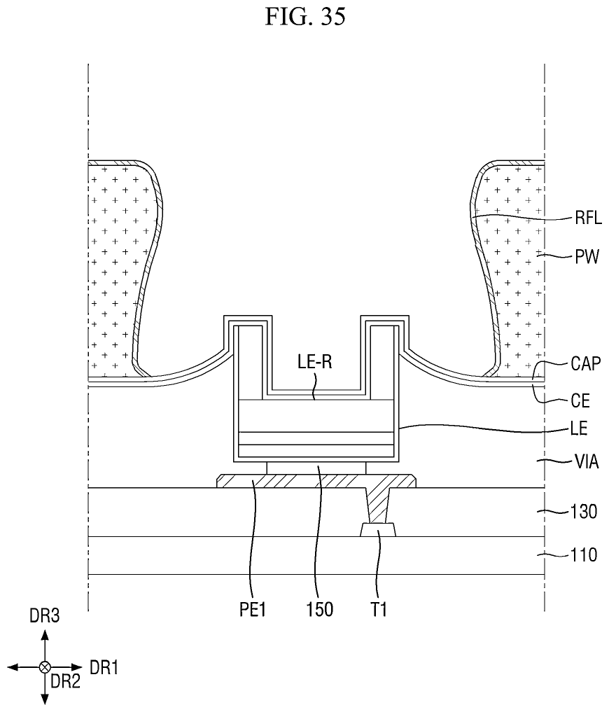

Next, referring to FIG. 35, the reflective material layer RFL is deposited on the entire surface of the substrate 110 on which the partition wall unit PW is formed. The reflective material layer RFL may be formed to cover the entire partition wall unit PW. The reflective material layer RFL may be formed on the top and side surfaces of the partition wall unit PW. The reflective material layer RFL may include, for example, aluminum (Al) or silver (Ag), or may be an alloy thereof.

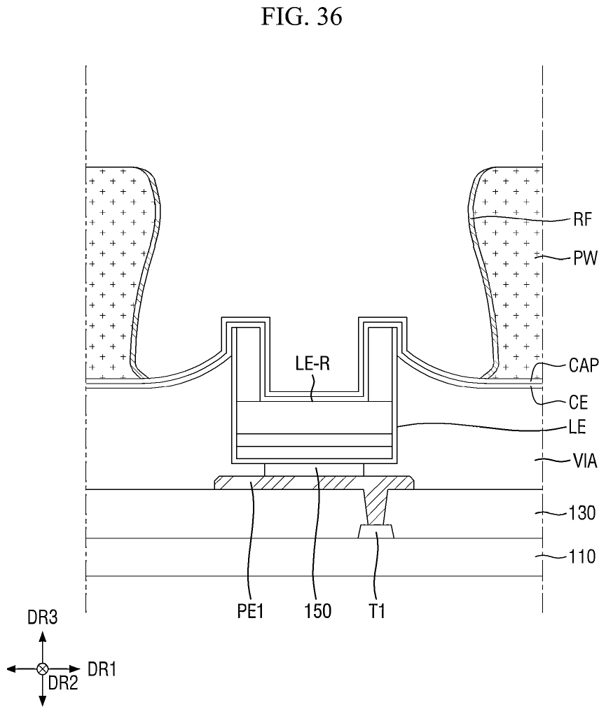

Referring to FIG. 36, the reflective material layer RFL is partially etched to form the reflective layer RF on the side of the partition wall unit PW.

For example, a large voltage difference is formed in the third direction DR3, and the reflective material layer RFL is etched with the etching material. In this case, the etching material moves in the third direction DR3 (e.g., from the top to the bottom), and the reflective layer RF may be etched. As a result, the reflective material layer RFL located on the horizontal plane defined by the first direction DR1 and the second direction DR2 is removed, while the reflective material layer RFL located on the vertical plane defined by the third direction DR3 may not be removed. Therefore, the reflective material layer RFL located on the top surface of the partition wall unit PW and the capping layer CAP is removed, and only the reflective material layer RFL remains on the side of the partition wall unit PW to form the reflective layer RF.

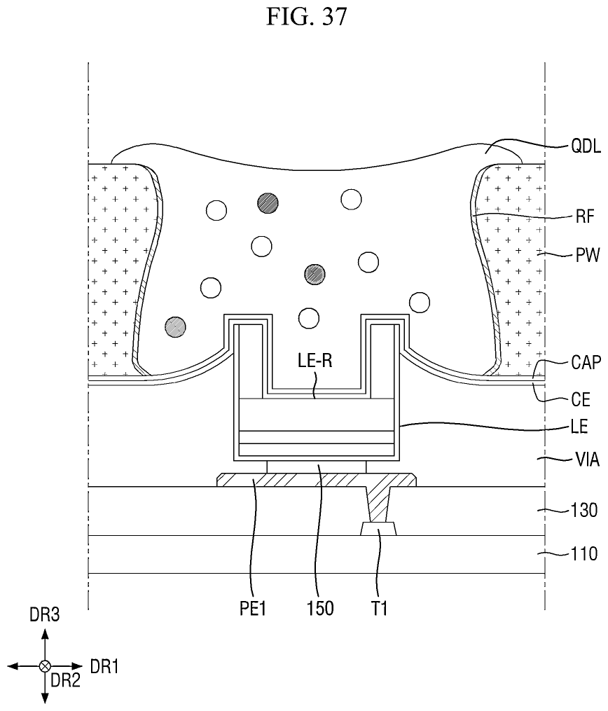

Referring to FIG. 37, the wavelength conversion layer QDL is formed in the space formed by the partition wall unit PW.

The wavelength conversion layer QDL may be formed through a solution process, such as imprinting but is not limited thereto. The wavelength conversion layer QDL may be formed to fill the space formed by the partition wall unit PW.

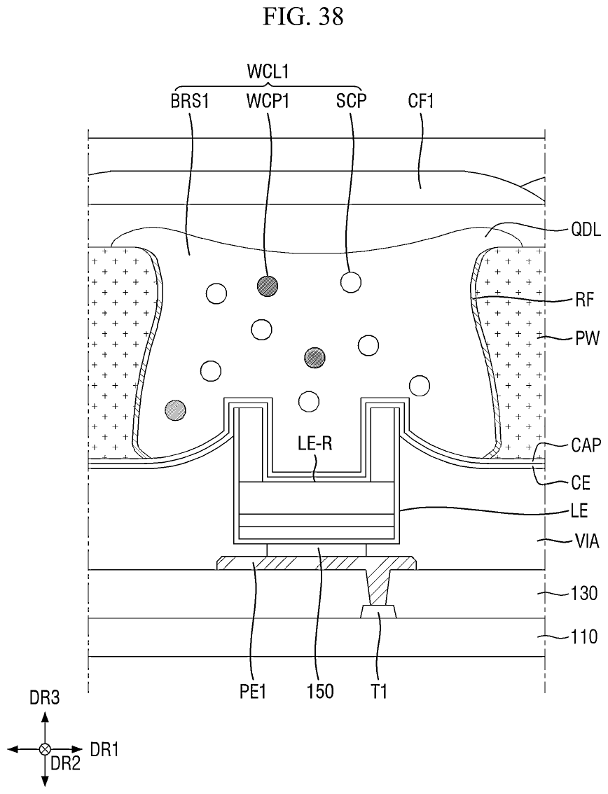

Next, as shown in FIG. 38 and with reference to FIG. 6, the display device 10 according to one or more embodiments is manufactured by forming the color filter layer CFL on the substrate 110. The color filter layer CFL may form the first overcoat layer OC1, the first color filter CF1, and the second overcoat layer OC2.

The first color filter CF1 may be formed through a photolithography process. For example, the color filter layer is formed by applying a color filter material layer on the wavelength conversion layer QDL and the partition wall PW, and by patterning the color filter material layer through the photolithography process to form the color filter CF that overlaps the wavelength conversion layer QDL. The thickness of the color filter CF may be about 1 μm or less but is not limited thereto.

According to one or more embodiments, the second semiconductor layer SEM2 and the common electrode CE are in direct contact through the recess LE-R formed on the top surface of the light-emitting element LE to reduce the contact resistance of the common electrode CE. This may improve power consumption.

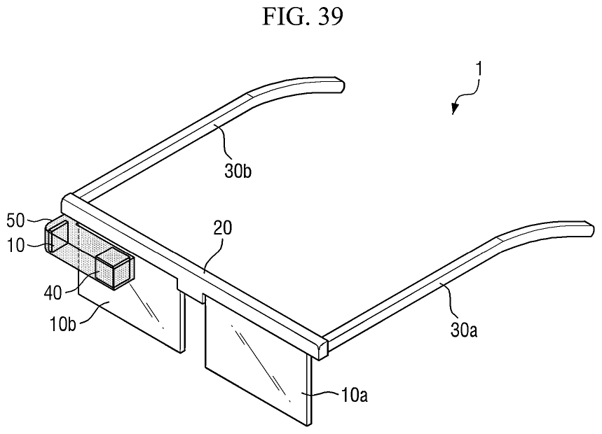

FIG. 39 is a diagram illustrating a virtual reality device including a display device according to one or more embodiments. FIG. 39 illustrates a virtual reality device 1 in which the display device 10 according to one or more embodiments is used.

Referring to FIG. 39, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 39 illustrates the virtual reality device 1 including the two legs 30a and 30b. However, the disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 39, and may be applied in various forms in various electronic devices.

The display device housing 50 may receive the display device 10 and the reflective member 40. An image displayed on the display device 10 may be reflected from the reflective member 40, and may be provided to a user's right eye through the right-eye lens 10b. Thus, the user may view a virtual reality image displayed on the display device 10 via the right eye.

FIG. 39 illustrates that the display device housing 50 is located at a right end of the support frame 20. However, one or more embodiments of the disclosure is not limited thereto. For example, the display device housing 50 may be located at a left end of the support frame 20. In this case, the image displayed on the display device 10 may be reflected from the reflective member 40, and may be provided to the user's left eye via the left-eye lens 10a. Thus, the user may view the virtual reality image displayed on the display device 10 via the left eye. As another example, the display device housing 50 may be located at each of the left end and the right end of the support frame 20. In this case, the user may view the virtual reality image displayed on the display device 10 via both the left eye and the right eye.

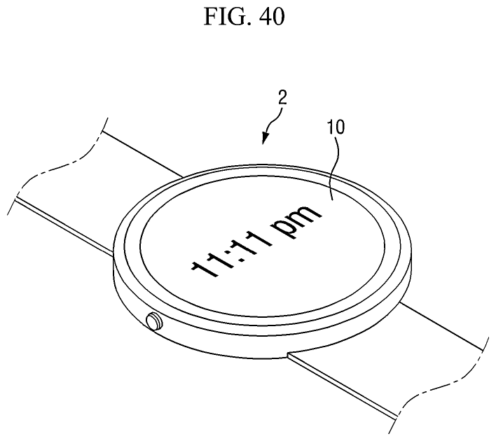

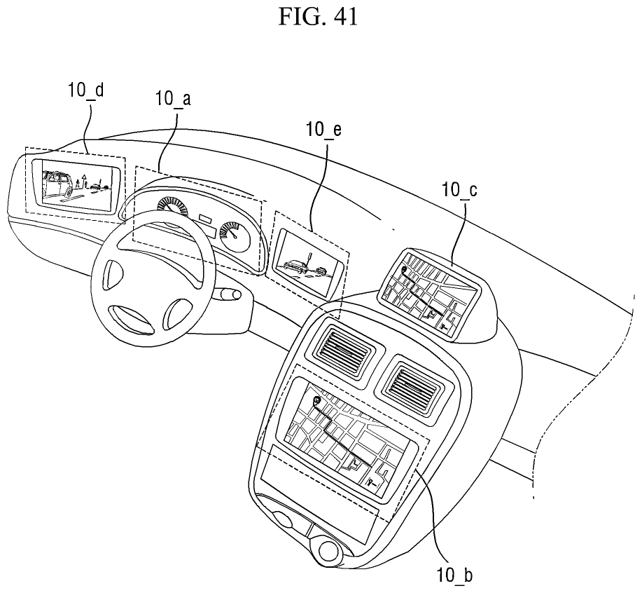

FIG. 40 is a diagram illustrating a smart device including a display device according to one or more embodiments.

Referring to FIG. 40, a display device 10 according to one or more embodiments may be applied to a smart watch 2 as one of smart devices.

FIG. 41 is a diagram illustrating a vehicle including a display device according to one or more embodiments. FIG. 41 illustrates a vehicle in which display devices according to one or more embodiments are used.

Referring to FIG. 41, the display devices 10_a, 10_b, and 10_c according to one or more embodiments may be applied to the dashboard of the vehicle, applied to the center fascia of the vehicle, or applied to a CID (Center Information Display) located on the dashboard of the vehicle. Further, each of the display devices 10_d and 10_e according to one or more embodiments may be applied to each room mirror display that replaces each of side-view mirrors of the vehicle.

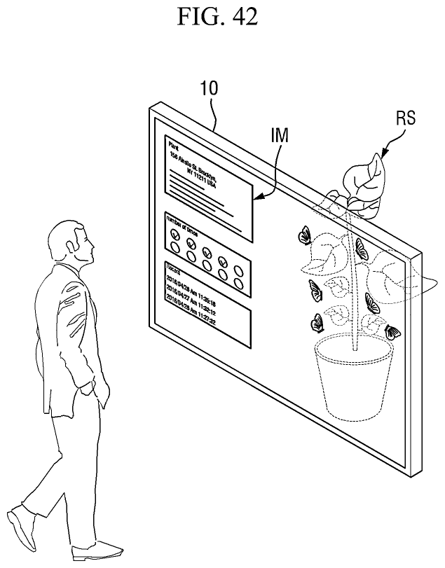

FIG. 42 is a diagram illustrating a transparent display device including a display device according to one or more embodiments.

Referring to FIG. 42, a display device 10 according to one or more embodiments may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the substrate 110 of the display device 10 shown in FIG. 7 may include a light-transmitting portion that may transmit light therethrough or may be made of a material that may transmit light therethrough.

In concluding the detailed description, those skilled in the art will appreciate that many variations and modifications can be made to the embodiments without substantially departing from the aspects of the disclosure. Therefore, the disclosed embodiments of the disclosure are used in a generic and descriptive sense only and not for purposes of limitation.

What is claimed is:

1. A display device comprising:
a pixel electrode above a substrate;
a light-emitting element above the pixel electrode, and comprising a first semiconductor layer, an active layer, a second semiconductor layer, and a third semiconductor layer in sequence, the third semiconductor layer defining a recess exposing a portion of the second semiconductor layer;
a via layer above the substrate, and surrounding at least a portion of the light-emitting element; and
a common electrode above the light-emitting element and the via layer, and directly contacting the second semiconductor layer through the recess.

2. The display device of claim 1, further comprising:
a partition wall unit above the common electrode, and defining a light-emitting area; and
a wavelength conversion layer in a space formed by the partition wall unit, and filling the recess.

3. The display device of claim 2, wherein the wavelength conversion layer comprises a wavelength conversion pattern comprising a base resin and wavelength conversion particles, or comprises a light transmission pattern comprising a base resin and a scatterer.

4. The display device of claim 3, wherein the wavelength conversion layer further comprises a scattering layer comprising the base resin and the scatterer below the wavelength conversion pattern.

5. The display device of claim 3, wherein a width of the recess is between about 40% and about 90% of a width of the light-emitting element.

6. The display device of claim 2, further comprising an element-insulating layer surrounding the light-emitting element in plan view; and
a connection electrode between the first semiconductor layer and the pixel electrode.

7. The display device of claim 2, further comprising a capping layer above and covering the common electrode.

8. The display device of claim 2, wherein a height of the via layer is lower than a height of the light-emitting element.

9. The display device of claim 2, wherein the partition wall unit comprises a first partition wall having an inverted taper shape with a width narrowing in a downward direction, and a first reflective layer surrounding the first partition wall in plan view.

10. The display device of claim 9, wherein the partition wall unit comprises a second partition wall above the first partition wall and having an inverted taper shape with a width narrowing in the downward direction, and a second reflective layer surrounding the second partition wall in plan view.

11. The display device of claim 6, further comprising:
an organic pattern layer between the connection electrode and the pixel electrode; and
a sub-connection electrode extending along a side surface of the connection electrode to a side surface of the pixel electrode, and electrically connecting the connection electrode and the pixel electrode.

12. The display device of claim 11, wherein the pixel electrode protrudes outwardly further than a side of the organic pattern layer.

13. The display device of claim 11, wherein the partition wall unit comprises a first partition wall having an inverted taper shape with a width narrowing in a downward direction, and a first reflective layer surrounding the first partition wall in plan view.

14. The display device of claim 13, wherein the partition wall unit comprises a second partition wall above the first partition wall and having an inverted taper shape with a width narrowing in the downward direction, and a second reflective layer surrounding the second partition wall in plan view.

15. The display device of claim 9, further comprising an overcoat layer and a color filter layer sequentially above the wavelength conversion layer and the partition wall unit.

16. A method of manufacturing display device, the method comprising:
bonding a light-emitting element, which comprises a first semiconductor layer, an active layer, a second semiconductor layer, and a third semiconductor layer, to a pixel electrode above a substrate;
forming a via layer having a height that is lower than a height of the light-emitting element above the substrate;
forming a photoresist pattern surrounding the light-emitting element in plan view above the via layer;
forming a recess in the third semiconductor layer to expose a portion of the second semiconductor layer by etching using the photoresist pattern as a mask; and
forming a common electrode covering the via layer and the light-emitting element, and directly contacting the second semiconductor layer through the recess.

17. The method of claim 16, further comprising:
forming a partition wall unit defining a light-emitting area above the common electrode;
forming a reflective layer surrounding the partition wall unit in plan view; and
forming a wavelength conversion layer in a space formed by the partition wall unit.

18. The method of claim 17, further comprising forming a scattering layer comprising a base resin and a scatterer in the light-emitting area above the common electrode.

19. The method of claim 17, wherein the light-emitting element further comprises a connection electrode below the first semiconductor layer, and
wherein the bonding the light-emitting element to the pixel electrode comprises melt bonding using the connection electrode above the pixel electrode.

20. The method of claim 17, wherein the light-emitting element further comprises a connection electrode below the first semiconductor layer, and
wherein bonding the light-emitting element to the pixel electrode comprises:
forming an organic pattern layer between the pixel electrode and the connection electrode; and
forming a sub-connection electrode contacting the pixel electrode and the connection electrode.
